(19) United States
(12) Patent Application Publication
(10) Pub. No.: US 2025/0296127 A1
(43) Pub. Date: Sep. 25, 2025

(54) SUBSTRATE PROCESSING APPARATUS AND SUBSTRATE PROCESSING METHOD

(71) Applicant: SCREEN Holdings Co., Ltd., Kyoto (JP)

(72) Inventors: Michinori IWAO, Kyoto (JP); Yukifumi YOSHIDA, Kyoto (JP); Tomohiro UEMURA, Kyoto (JP); Shoyo MINAMI, Kyoto (JP); Yusuke UEDA, Kyoto (JP)

(21) Appl. No.: 19/071,657

(22) Filed: Mar. 5, 2025

(30) Foreign Application Priority Data
Mar. 21, 2024 (JP) 2024-044507

(51) Int. Cl. B08B 3/14; B01D 61/36; B08B 3/02; B08B 3/08; B08B 13/00; C02F 1/44; C02F 103/34; F25B 39/04; H01L 21/67

(52) U.S. Cl. CPC B08B 3/14; B01D 61/363; B01D 61/366; B08B 3/02; B08B 3/08; B08B 13/00; C02F 1/44; F25B 39/04; B01D 2313/18; B01D 2313/701; B01D 2313/903; C02F 2103/346; C02F 2201/005; C02F 2209/006; C02F 2209/40; H01L 21/67051

(57) ABSTRACT

A substrate processing apparatus includes: a collection tank storing a mixed fluid containing water and an organic solvent; a dewaterer disposed in a pipe connected to the collection tank, and including a separation membrane allowing the water to pass through and does not allow the organic solvent to pass through; a separation pipe which is connected to the dewaterer and into which separated water that has passed through the separation membrane flows; a concentration monitoring sensor measuring a concentration of the organic solvent contained in the separated water; a shut-off valve disposed in the separation pipe, and shutting off a flow of the separated water when the shut-off valve is in a closed state; and a controller closing the shut-off valve when the concentration of the organic solvent measured by the concentration monitoring sensor exceeds a safe concentration lower than a lower explosion limit of the organic solvent.

### BACKGROUND

### Technical Field

The present disclosure relates to a substrate processing apparatus and a substrate processing method.

### Description of the Background Art

In substrate processing apparatuses used in manufacturing steps of semiconductor devices, etc., for example, a substrate is processed with a chemical liquid, and then rinsed out with a rinse liquid. In Japanese Patent Application Laid-Open No. 2017-41505, a substrate rinsed out with a rinse liquid (i.e., a substrate covered with a rinse liquid (typically, water)) is supplied with isopropyl alcohol (IPA) to replace the rinse liquid on the substrate with IPA. Then, the substrate is rotated at high speeds to blow off the IPA that adheres to the substrate, and is dried. When rotating the substrate at high speeds to blow off the adhering liquid, there is a risk that the surface tension of the adhering liquid may collapse a pattern. However, previous replacement of the water that adheres to the substrate with IPA with a surface tension lower than that of water suppresses the collapse of the pattern. Since IPA is bipolar, even when the surface of the substrate is hydrophobic, the substrate can evenly become wet. Thus, the dried substrate hardly has watermarks.

When a flammable substance such as IPA is handled, an area in which the substance is handled is defined as an explosion-proof area. For example, electrical devices to be disposed in the explosion-proof area (devices that are in danger of becoming sources of ignition) require explosion-proof measures to prevent the devices from becoming sources of ignition. Obviously, the wider the explosion-proof area is, the more the number of devices requiring explosion-proof measures increases.

### SUMMARY

The present disclosure is directed to a substrate processing apparatus. The substrate processing apparatus according to one aspect of the disclosure includes: a rinse liquid supply nozzle that supplies a substrate with a rinse liquid containing water; an organic solvent supply nozzle that supplies an organic solvent to the substrate; a collection tank that stores a mixed fluid containing the water supplied to the substrate and then collected and the organic solvent supplied to the substrate and then collected; a dewaterer disposed in a pipe connected to the collection tank, and including a separation membrane that allows the water to pass through and does not allow the organic solvent to pass through; a separation pipe which is connected to the dewaterer and into which separated water that has passed through the separation membrane flows; a concentration monitoring sensor that measures a concentration of the organic solvent contained in the separated water; a shut-off valve disposed in the separation pipe, and shutting off a flow of the separated water through the separation pipe when the shut-off valve is in a closed state; and a controller that closes the shut-off valve when the concentration of the organic solvent measured by the concentration monitoring sensor exceeds a safe concentration lower than a lower explosion limit of the organic solvent.

The present disclosure is also directed to a substrate processing method. The substrate processing method according to one aspect of the disclosure includes: supplying a substrate with a rinse liquid containing water; supplying an organic solvent to the substrate; storing, in a collection tank, a mixed fluid containing the water supplied to the substrate and then collected and the organic solvent supplied to the substrate and then collected; causing the mixed fluid stored in the collection tank to flow through a pipe in which a dewaterer is disposed, the dewaterer including a separation membrane that allows the water to pass through and does not allow the organic solvent to pass through; causing separated water to flow into a separation pipe, the separated water being separated from the mixed fluid flowing into the dewaterer; determining whether a concentration of the organic solvent contained in the separated water flowing through the separation pipe exceeds a safe concentration lower than a lower explosion limit of the organic solvent; and closing a shut-off valve disposed in the separation pipe when it is determined that the concentration of the organic solvent exceeds the safe concentration to shut off a flow of the separated water through the separation pipe.

Thus, the object of this disclosure is to provide a technology that can narrow an explosion-proof area without compromising safety.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically illustrating an example structure of a substrate processing apparatus;

FIG. 2 is a side view schematically illustrating an example structure of a processing unit;

FIG. 3 schematically illustrates an example structure of an organic solvent collector;

FIG. 4 is a side sectional view schematically illustrating an example structure of a dewaterer;

FIG. 5 illustrates an example procedure to be performed by the organic solvent collector;

FIG. 6 illustrates an example procedure for separating water from a mixed fluid and an example procedure for monitoring the concentration of IPA contained in the separated water;

FIG. 7 is a diagram for illustrating Step S1;

FIG. 8 is a diagram for illustrating Step S201;

FIG. 9 is a diagram for illustrating Step S202;

FIG. 10 is a diagram for illustrating Step S213a and Step S213b;

FIG. 11 is a diagram for illustrating Step S205;

FIG. 12 is a diagram for illustrating Step S3;

FIG. 13 is a diagram for illustrating Step S4;

FIG. 14 schematically illustrates an example structure of the organic solvent collector according to a modification; and

FIG. 15 schematically illustrates an example structure of the organic solvent collector according to a modification.

### DESCRIPTION OF THE PREFERRED EMBODIMENTS

An embodiment will be described below with reference to the attached drawings. The constituent elements described in the embodiment are mere exemplification, and only the exemplification does not intend to limit the scope of the disclosure. The drawings are drawn in schematic form, structures are appropriately omitted or simplified, and the dimensions and the number of parts are illustrated in exaggeration or simplified for convenience in description. The position relationships between the structures in the drawings are not necessarily accurately illustrated.

Unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, and “homogeneous”) include those indicating quantitatively exact equality and those in the presence of a difference within tolerance or to the extent that similar functions can be obtained. Unless otherwise noted, the expressions indicating shapes (e.g., “circular”, “oval”, “rectangular” or “cylindrical”) include those indicating geometrically exact shapes and those indicating, for example, roughness or a chamfer to the extent that similar advantages can be obtained. An expression “comprising”, “including”, “containing”, or “having” one or more constituent elements is not an exclusive expression for excluding the presence of the other constituent elements. An expression “at least one of A, B, or C” involves “only A”, “only B”, “only C”, “any two of A, B, and C”, and “all of A, B, and C”. Even when the ordinal numbers such as “first” and “second” are used, these terms are used for convenience to facilitate the understanding of the details of the embodiment. The order indicated by these ordinal numbers does not restrict the details of the embodiment.

### 1. Substrate Processing Apparatus

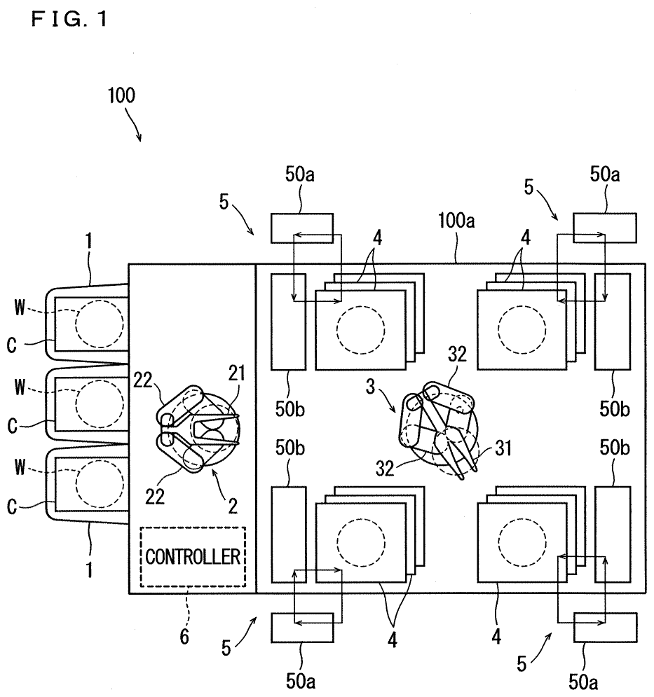

A substrate processing apparatus 100 according to the embodiment will be described with reference to FIG. 1. FIG. 1 is a plan view schematically illustrating an example structure of the substrate processing apparatus 100.

The substrate processing apparatus 100 is a single-wafer processing apparatus that processes (treats) substrates W to be processed one by one. The substrate W to be processed by the substrate processing apparatus 100 is, for example, a semiconductor substrate. The shape of the substrate W to be processed is, for example, disk-shaped.

The substrate processing apparatus 100 includes load ports 1, an indexer robot 2, a main transport robot 3, processing units 4, organic solvent collectors 5, and a controller 6.

Each of the load ports 1 is an interface for transporting the substrate W into and out of a carrier C that is a sort of a container that houses a plurality of the substrates W. The number of the load ports 1 is, for example, multiple (three in the example of the drawing). The load ports 1 are, for example, horizontally aligned in a row. The carriers C may be of a type that houses the substrates W in an airtight space (e.g., a front opening unified pod (FOUP) or a standard mechanical interface (SMIF) pod), or of a type that exposes the substrates W to outside air (e.g., an open cassette (OC)).

The indexer robot 2 is a transporter that transports the substrate W. The indexer robot 2 is, for example, a horizontal articulated robot, and includes a pair of hands 21 that hold the substrate W, and an arm 22 that is connected to each of the hands 21. Furthermore, the indexer robot 2 includes a driving mechanism (not illustrated) for rotating each of the hands 21 and flexing, rotating, and raising and lowering each of the arms 22. The indexer robot 2 transports the substrate W between each of the carriers C placed on the load ports 1 and the main transport robot 3. In other words, the indexer robot 2 accesses each of the carriers C placed on the load ports 1 to perform an unloading operation (i.e., an operation of unloading the substrate W housed in the carrier C using the hands 21) and perform a loading operation (i.e., an operation of loading the substrate W held by the hands 21 into the carrier C). Furthermore, the indexer robot 2 accesses a transfer position to transfer the substrate W to and from the main transport robot 3.

The main transport robot 3 is a transporter that transports the substrate W. The main transport robot 3 is, for example, a horizontal articulated robot, and includes a pair of hands 31 that hold the substrate W, and an arm 32 that is connected to each of the hands 31. Furthermore, the main transport robot 3 includes a driving mechanism (not illustrated) for rotating each of the hands 31 and flexing, rotating, and raising and lowering each of the arms 32. The main transport robot 3 transports the substrate W between the indexer robot 2 and each of the processing units 4. In other words, the main transport robot 3 accesses a transfer position to transfer the substrate W to and from the indexer robot 2. Furthermore, the main transport robot 3 accesses each of the processing units 4 to perform a loading operation (i.e., an operation of loading the substrate W held by the hands 31 into the processing unit 4) and perform an unloading operation (i.e., an operation of unloading the substrate W in the processing unit 4 using the hands 31).

Each of the processing units 4 subjects the substrate W to a predetermined processing using processing liquids (e.g., a chemical liquid, a rinse liquid, and an organic solvent). For example, the plurality of processing units 4 (e.g., three processing units 4) stacked in a vertical direction compose one tower. The plurality of towers (e.g., four towers in the example of the drawing) are placed around the main transport robot 3. The specific structure of the processing unit 4 will be described later.

Each of the organic solvent collectors 5 collects the organic solvent that has been used for the processing in the processing unit 4, and supplies the organic solvent to the processing unit 4 again. Here, the organic solvent collectors 5 as many as the towers are provided. The organic solvent collectors 5 correspond one-to-one with the towers. Each of the organic solvent collectors 5 collects the organic solvent that has been used for the processing in the respective processing units 4 included in the corresponding tower, and supplies the organic solvent to the respective processing units 4 included in the corresponding tower again. The specific structure of the organic solvent collector 5 will be described later.

The controller 6 controls operations of parts included in the substrate processing apparatus 100 (the load ports 1, the indexer robot 2, the main transport robot 3, the processing units 4, and the organic solvent collectors 5). The controller 6 is implemented by, for example, a common computer with an electrical circuit. The controller 6 includes, for example, a central processing unit (CPU) that performs various computation processes (data processes), a read-only memory (ROM) for storing a basic program, etc., a random access memory (RAM) used as a work area when the CPU performs a predetermined process (a data process), a storage device (specifically, for example, non-volatile storage devices such as a flash memory and a hard disk device), and a bus line that mutually connects these. The storage device or the RAM may store a program for defining processes to be executed by the controller 6. Here, for example, the CPU executes the program, so that the controller 6 may control the parts included in the substrate processing apparatus 100 and the substrate processing apparatus 100 may execute the processes defined by the program. In other words, the CPU executes the program, so that the controller 6 may implement a circuit that executes the processes defined by the program. Obviously, hardware such as a dedicated logic circuit may execute (implement) a part or the entire control to be performed by the controller 6 (a part or the entire circuit to be implemented by the controller 6).

### 2. Processing Unit

### 2-1. Structure of Processing Unit

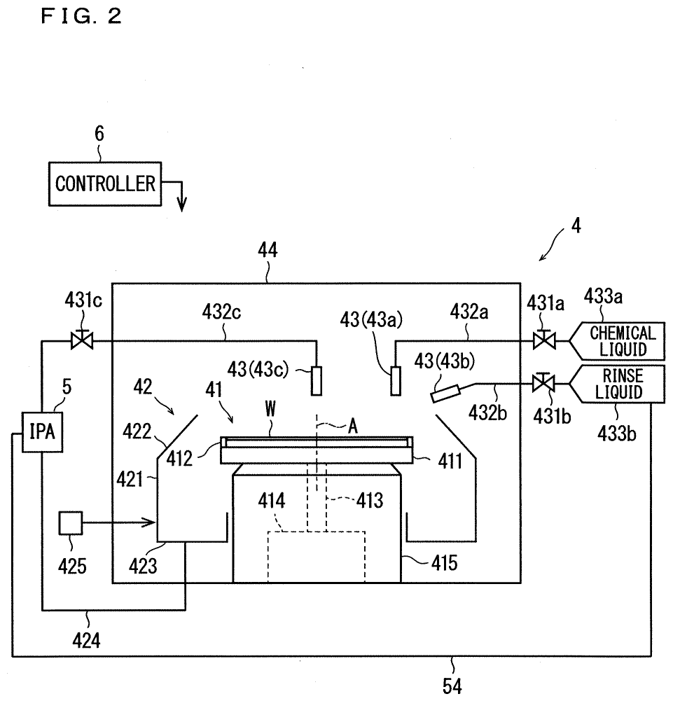

The structure of the processing unit 4 will be described below with reference to FIG. 2. FIG. 2 is a side view schematically illustrating an example structure of the processing unit 4.

Each of the processing units 4 subjects the substrate W to a predetermined processing using processing liquids (e.g., a chemical liquid, a rinse liquid, and an organic solvent). The processing unit 4 includes, for example, a spin chuck 41, a cup 42, and nozzles 43. The spin chuck 41, the cup 42, and the nozzles 43 are housed in a processing chamber 44.

The spin chuck 41 rotates the substrate W about an axis line (a rotation axis line) A that passes through the center of the main surface of the substrate W and extends in the upward and downward direction, while holding the substrate W in a horizontal attitude (an attitude with which the thickness direction of the substrate W is along the upward and downward direction (vertical direction)). The spin chuck 41 includes, specifically for example, a spin base 411. The spin base 411 is a disk-shaped part, and is disposed in an attitude such that the thickness direction is along the upward and downward direction. A plurality of chuck pins 412 are arranged on the upper surface of the spin base 411. The chuck pins 412 are arranged at regular intervals along the circumference corresponding to the outer edge of the substrate W. A linkage mechanism (not illustrated), which moves the chuck pins 412 between an abutment position and an open position, is connected to the chuck pins 412. The abutment position is a position at which the chuck pins 412 abut the outer edge of the substrate W. The open position is a position at which the chuck pins 412 are away from the outer edge of the substrate W. When each of the chuck pins 412 is disposed at the abutment position, the substrate W is held (chucked) in a horizontal attitude above the spin base 411. When each of the chuck pins 412 is disposed at the open position, hold of the substrate W is released. The linkage mechanism switches the positions of the chuck pins 412 according to an instruction from the controller 6. In other words, the controller 6 controls, for example, the timing to hold the substrate W and the timing to release the hold of the substrate W. Furthermore, the spin base 411 is connected to a spin motor 414 through a shaft 413 disposed coaxial with the rotation axis line A. The shaft 413 and the spin motor 414 are housed in a cover 415. The spin motor 414 rotates the shaft 413 about the rotation axis line A. This allows the spin base 411 and further the substrate W held above the spin base 411 to rotate about the rotation axis line A. The spin motor 414 rotates the spin base 411 according to an instruction from the controller 6. In other words, the controller 6 controls, for example, the rotation speed, the rotation start timing, and the rotation end timing of the spin base 411 (further the substrate W).

The cup 42 receives the processing liquid discharged from the substrate W that is held and rotated by the spin chuck 41. The cup 42 specifically includes, for example, a cylindrical guide part 421 disposed coaxial with the rotation axis line A, a slope 422 that is continuous from the upper end of the guide part 421 and has a diameter that becomes smaller toward the top, and a liquid receiver 423 that is continuous from the lower end of the guide part 421 and forms an annular groove that is opened upward. The liquid receiver 423 is equipped with cup-side collecting pipes that collect the liquid received herein. Here, for example, the cup-side collecting pipes include a cup-side collecting pipe for the chemical liquid (not illustrated) and a cup-side collecting pipe 424 for the organic solvent. Furthermore, a cup elevating mechanism 425 that moves the cup 42 up and down between a lower position and an upper position is connected to the cup 42. The lower position is a position at which the upper end of the cup 42 (specifically, the upper end of the slope 422) is located below the substrate W held by the spin chuck 41. The upper position is a position at which the upper end of the cup 42 is located above the substrate W held by the spin chuck 41. The cup elevating mechanism 425 moves the cup 42 up and down according to an instruction from the controller 6. In other words, the controller 6 controls the position of the cup 42.

The nozzles 43 each discharge (dispense) a processing liquid toward the upper surface of the substrate W held by the spin chuck 41. Here, for example, the nozzles 43 are separately provided for each type of processing liquids. In other words, the nozzles 43 include the nozzle 43 for discharging a chemical liquid (also hereinafter referred to as a “chemical liquid nozzle 43a”), the nozzle 43 for discharging a rinse liquid (also hereinafter referred to as a “rinse liquid nozzle 43b”), and the nozzle 43 for discharging an organic solvent (also hereinafter referred to as an “organic solvent nozzle 43c”).

The chemical liquid nozzle 43a discharges a chemical liquid toward the upper surface of the substrate W held by the spin chuck 41. The chemical liquid nozzle 43a is connected to a chemical liquid supply source 433a through a chemical liquid pipe 432a into which a chemical liquid valve 431a is inserted. Once the chemical liquid valve 431a is opened, a chemical liquid is supplied to the chemical liquid nozzle 43a through the chemical liquid pipe 432a, and the chemical liquid is discharged from the chemical liquid nozzle 43a. The chemical liquid valve 431a is opened and closed according to an instruction from the controller 6. In other words, the controller 6 controls the timing to discharge the chemical liquid from the chemical liquid nozzle 43a. The chemical liquid is, for example, fluoric acid. The chemical liquid is not limited to fluoric acid, but may be at least one of sulfuric acid, acetic acid, nitric acid, hydrochloric acid, hydrofluoric acid, phosphoric acid, ammonia water, a hydrogen peroxide solution, organic acid (e.g., citric acid and oxalic acid), organic alkali (e.g. tetramethylammonium hydroxide (TMAH)), a surface active agent, or a corrosion inhibitor.

The rinse liquid nozzle 43b discharges a rinse liquid toward the upper surface of the substrate W held by the spin chuck 41. In other words, the rinse liquid nozzle 43b functions as a rinse liquid supply nozzle (a rinse liquid supply part) that supplies a rinse liquid to the substrate W herein. The rinse liquid nozzle 43b is connected to a rinse liquid supply source 433b through a rinse liquid pipe 432b into which a rinse liquid valve 431b is inserted. Once the rinse liquid valve 431b is opened, a rinse liquid is supplied to the rinse liquid nozzle 43b through the rinse liquid pipe 432b, and the rinse liquid is discharged from the rinse liquid nozzle 43b. The rinse liquid valve 431b is opened and closed according to an instruction from the controller 6. In other words, the controller 6 controls the timing to discharge the rinse liquid from the rinse liquid nozzle 43b. Here, the rinse liquid is water (specifically, for example, pure water (deionized water)).

The organic solvent nozzle 43c discharges an organic solvent toward the upper surface of the substrate W held by the spin chuck 41. In other words, the organic solvent nozzle 43c functions as an organic solvent supply nozzle (an organic solvent supply part) that supplies an organic solvent to the substrate W herein. The organic solvent nozzle 43c is connected to the organic solvent collector 5 through an organic solvent pipe 432c into which an organic solvent valve 431c is inserted. Once the organic solvent valve 431c is opened, an organic solvent (an organic solvent with sufficiently high purity, specifically, for example, an organic solvent with purity of 99 wt % or higher) is supplied to the organic solvent nozzle 43c through the organic solvent pipe 432c, and is discharged from the organic solvent nozzle 43c. The organic solvent valve 431c is opened and closed according to an instruction from the controller 6. In other words, the controller 6 controls the timing to discharge the organic solvent from the organic solvent nozzle 43c. The organic solvent is, for example, a water-soluble organic solvent. Here, the organic solvent is isopropyl alcohol (IPA).

A nozzle movement mechanism that moves at least one of the chemical liquid nozzle 43a, the rinse liquid nozzle 43b, or the organic solvent nozzle 43c between a processing position and a retracted position may be connected to the at least one nozzle. The processing position is a position at which the processing liquid discharged from the nozzle 43a, 43b, or 43c is supplied to the substrate W held by the spin chuck 41. The retracted position is a position of the nozzle 43a, 43b, or 43c that is located outside of the outer edge of the substrate W held by the spin chuck 41 (outward in a radial direction) when viewed from the top. Here, the nozzle movement mechanism moves the nozzle 43a, 43b, or 43c according to an instruction from the controller 6. In other words, the controller 6 controls the positions of the nozzle 43a, 43b, and 43c.

### 2-2. Operations of Processing Unit

Example operations of the processing unit 4 will be described with reference to FIG. 2 again.

The operations of the processing unit 4 are performed under control of the controller 6. In other words, the controller 6 controls, for example, the chuck pins 412, the spin motor 414, the cup elevating mechanism 425, the chemical liquid valve 431a, the rinse liquid valve 431b, and the organic solvent valve 431c, so that the processing unit 4 proceeds with a series of the operations.

Once the main transport robot 3 transports the substrate W into the processing chamber 44, the spin chuck 41 holds the substrate W. Then, the spin chuck 41 starts rotating.

In this state, the chemical liquid valve 431a is opened. Then, the chemical liquid nozzle 43a discharges the chemical liquid toward the upper surface of the substrate W held and rotated by the spin chuck 41. This supplies the chemical liquid to the entire region of the upper surface of the substrate W to process the substrate W with the chemical liquid (a chemical liquid supplying step). For example, when fluoric acid is used as the chemical liquid, the chemical liquid removes a foreign substance such as particles from the substrate W. During the chemical liquid supplying step, the cup 42 is located at the upper position.

Thus, the cup 42 receives the chemical liquid scattered around the substrate W. In other words, the chemical liquid scattered around the substrate W is received by the slope 422, is guided downward by the guide part 421, and is collected by the liquid receiver 423. The chemical liquid received by the cup 42 (i.e., the chemical liquid collected by the liquid receiver 423) is collected through the cup-side collecting pipe (not illustrated) for the chemical liquid.

After a lapse of a predetermined time since start of discharging the chemical liquid, the chemical liquid valve 431a is closed. Then, the chemical liquid nozzle 43a stops discharging the chemical liquid. Next, the rinse liquid valve 431b is opened. Then, the rinse liquid nozzle 43b discharges the rinse liquid toward the upper surface of the substrate W held and rotated by the spin chuck 41. This supplies the rinse liquid to the entire region of the upper surface of the substrate W to rinse out the chemical liquid that adheres to the substrate W with the rinse liquid (a rinse liquid supplying step). During the rinse liquid supplying step, the cup 42 is also located at the upper position. Thus, the cup 42 receives the chemical liquid and the rinse liquid scattered around the substrate W. The chemical liquid and the rinse liquid received by the cup 42 are collected through the cup-side collecting pipe (not illustrated) for the chemical liquid.

After a lapse of a predetermined time since start of discharging the rinse liquid, the rinse liquid valve 431b is closed. Then, the rinse liquid nozzle 43b stops discharging the rinse liquid. Next, the organic solvent valve 431c is opened. Then, the organic solvent nozzle 43c discharges IPA toward the upper surface of the substrate W held and rotated by the spin chuck 41. This supplies IPA to the entire region of the upper surface of the substrate W to replace the rinse liquid that adheres to the substrate W with IPA (an organic solvent supplying step). During the organic solvent supplying step, the cup 42 is also located at the upper position. Thus, the cup 42 receives the rinse liquid and the IPA scattered around the substrate W. The rinse liquid and the IPA received by the cup 42 are collected through the cup-side collecting pipe 424 for the organic solvent.

After a lapse of a predetermined time since start of supplying IPA, the organic solvent valve 431c is closed. Then, the organic solvent nozzle 43c stops discharging IPA. In this phase, the rinse liquid on the substrate W is completely replaced with IPA, and a liquid film of IPA covering the entire region of the upper surface of the substrate W is formed. Next, the spin chuck 41 starts rotating at high speeds. This allows the substrate W to rotate at high speeds to throw off the IPA on the substrate W around the substrate W by centrifugal force (a spin drying step). While the substrate W is rotated at high speeds, the cup 42 is also located at the upper position. Thus, the cup 42 receives the IPA scattered around the substrate W. The IPA received by the cup 42 is collected through the cup-side collecting pipe 424 for the organic solvent.

After a lapse of a predetermined time since the spin chuck 41 starts rotating at high speeds, the rotation of the spin chuck 41 is stopped. In this phase, the IPA is removed from the substrate W, and the substrate W is dried. The main transport robot 3 transports the dried substrate W out of the processing chamber 44.

As described above, a series of processes on the single substrate W is completed. In the processing unit 4, the aforementioned series of processes is repeated to process the substrates W one by one.

### 3. Organic Solvent Collector

### 3-1. Structure

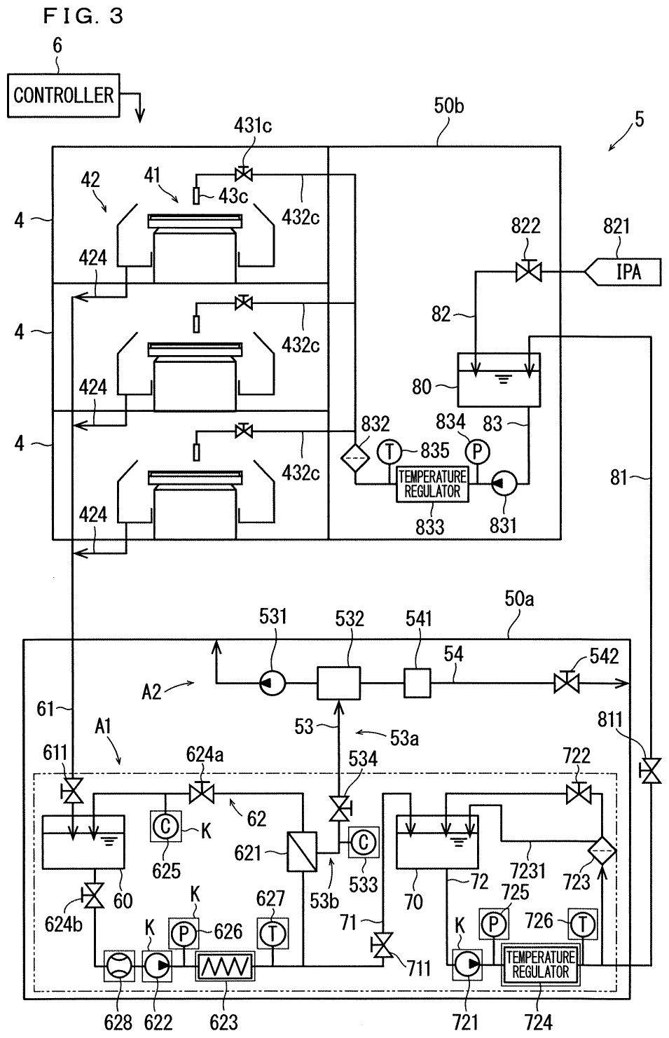

The structure of the organic solvent collector 5 will be described with reference to FIG. 3. FIG. 3 schematically illustrates an example structure of the organic solvent collector 5.

The organic solvent collector 5 includes a collection tank 60, a purification tank 70, and a supply tank 80. For example, a first storage box 50a houses the collection tank 60 and the purification tank 70, and a second storage box 50b houses the supply tank 80. For example, the first storage box 50a is disposed outside an external wall 100a of the substrate processing apparatus 100 (e.g., under a clean room in which the substrate processing apparatus 100 is installed (underground)), and the second storage box 50b is disposed inside the external wall 100a of the substrate processing apparatus 100 (FIG. 1).

### (a) Collection Tank 60

The collection tank 60 is connected to the cups 42 through a collection pipe 61. In other words, one end of the collection pipe 61 is connected to the collection tank 60, and the other end of the collection pipe 61 is connected to the cups 42 (specifically, the cup-side collecting pipes 424 connected to the cups 42). Here, for example, the collection pipe 61 is connected to the cup 42 included in each of the processing units 4 belonging to the same tower. A collection valve 611 is disposed in the collection pipe 61. Once the collection valve 611 is opened, the organic solvent (IPA herein) collected by the cups 42 in the organic solvent supplying step and the spin drying step is guided by the collection pipe 61, and flows into and is stored by the collection tank 60. The IPA (IPA with sufficiently high purity, specifically, for example, IPA with purity of 99 wt % or higher) is collected in the spin drying step, whereas IPA in a state where the IPA is mixed with the rinse liquid (water herein) (i.e., a state of being diluted with water) is collected in the organic solvent supplying step. Thus, the collection tank 60 stores a mixed fluid containing the water supplied to the substrate W and then collected in the processing unit 4 and the IPA supplied to the substrate W and then collected in the processing unit 4.

A circulation pipe (a dewatering circulation pipe) 62 is connected to the collection tank 60. Specifically, both of one end and the other end of the dewatering circulation pipe 62 are connected to the collection tank 60. The dewatering circulation pipe 62 forms a circulation path through which the mixed fluid stored in the collection tank 60 circulates by flowing out of the collection tank 60 and returning to the collection tank 60 again.

A dewaterer (separator) 621 is disposed in the dewatering circulation pipe 62. The dewaterer 621 separates water from the mixed fluid flowing into the dewaterer 621 to dewater the mixed fluid. The structure of the dewaterer 621 will be described later.

A pump (a dewatering feed pump 622), a heater 623, and a pair of open/close valves 624a and 624b are disposed in the dewatering circulation pipe 62. For example, the dewatering feed pump 622 is disposed downstream of the collection tank 60 and upstream of the dewaterer 621, and the heater 623 is disposed downstream of the dewatering feed pump 622 and upstream of the dewaterer 621. The one open/close valve 624a is disposed upstream of the collection tank 60, and the other open/close valve 624b is disposed downstream of the collection tank 60. The dewatering feed pump 622 feeds the mixed fluid in the dewatering circulation pipe 62 at a pressure necessary for circulation (a circulation pressure). The dewatering feed pump 622 feeds the mixed fluid at the circulation pressure with the pair of open/close valves 624a and 624b being opened, so that the mixed fluid stored in the collection tank 60 circulates through the dewatering circulation pipe 62. The heater 623 heats the mixed fluid circulating through the dewatering circulation pipe 62 to a predetermined temperature.

Various sensors may be disposed in the dewatering circulation pipe 62. For example, a concentration sensor 625 that measures the concentration of IPA contained in the mixed fluid that circulates through the dewatering circulation pipe 62, a pressure sensor 626 that detects the pressure of the mixed fluid that circulates through the dewatering circulation pipe 62, a temperature sensor 627 that detects the temperature of the mixed fluid that circulates through the dewatering circulation pipe 62, and a flow rate sensor (flowmeter) 628 that measures the flow rate of the mixed fluid that circulates through the dewatering circulation pipe 62 may be disposed in the dewatering circulation pipe 62. In the example of the drawing, the concentration sensor 625 is disposed in the vicinity upstream of the collection tank 60, the pressure sensor 626 is disposed in the vicinity downstream of the dewatering feed pump 622, the temperature sensor 627 is disposed in the vicinity downstream of the heater 623, and the flow rate sensor 628 is disposed in the vicinity upstream of the dewatering feed pump 622.

### (b) Dewaterer 621

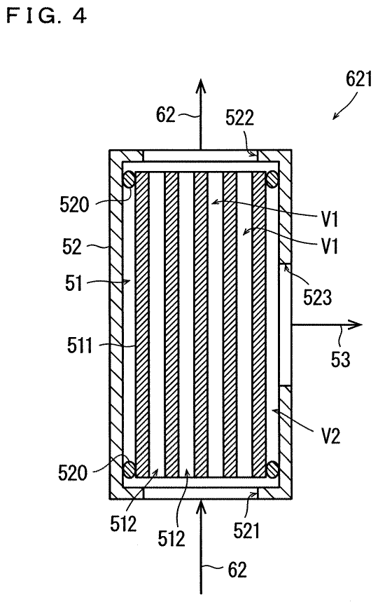

Next, the dewaterer 621 will be described with reference to FIG. 4 in addition to FIG. 3. FIG. 4 is a side sectional view schematically illustrating an example structure of the dewaterer 621.

The dewaterer 621 includes a separation membrane 51 and a housing 52.

The separation membrane 51 is a membrane that allows water to pass through and does not allow an organic solvent (IPA herein) to pass through (the separation membrane 51 blocks the passage of the organic solvent). The separation membrane 51 is, specifically for example, a zeolite membrane made of zeolite. Zeolite has, for example, a crystal structure in which base units of a tetrahedral structure (e.g., base units each including at least one of (SiO₄)⁴⁻ or (AlO₄)⁵⁻) are mutually coupled. The separation membrane 51 has, specifically for example, a structure including a myriad of cells 512 penetrating a cylindrical base body 511 in an axis direction. The cells 512 form the flow paths of the mixed fluid in the separation membrane 51. The entire base body 511 may be made of zeolite or only the inner circumferential surface of each of the cells 512 may be made of zeolite.

The housing 52 is a hollow and cylindrical component, and houses the separation membrane 51 inside. A pair of sealants 520 which seals a portion between the housing 52 and the separation membrane 51 housed in the housing 52 is provided between the housing 52 and the separation membrane 51. Each of the pairs of sealants 520 is, for example, ring-shaped, and is disposed at one end and the other end of the separation membrane 51 in the axis direction. The internal space of the housing 52 is separated by the separation membrane 51 into a cell internal space V1 that is an internal space of the separation membrane 51 (i.e., an internal space of the cells 512), and a separation space V2 that is an external space of the separation membrane 51. Furthermore, the housing 52 has an inlet 521, a first outlet 522, and a second outlet 523. The inlet 521 is disposed at one end face of the housing 52 in the axis direction, and communicates with the cell internal space V1 through one opening of each of the cells 512. The first outlet 522 is disposed at the other end face of the housing 52 in the axis direction, and communicates with the cell internal space V1 through the other opening of each of the cells 512. The second outlet 523 is disposed at the side surface (a peripheral surface) of the housing 52, and communicates with the separation space V2.

The dewatering circulation pipe 62 is connected to the inlet 521 and the first outlet 522. A separation pipe 53 equipped with a vacuum pump 531 is connected to the second outlet 523. The mixed fluid flowing through the dewatering circulation pipe 62 flows from the inlet 521 into the dewaterer 621 (specifically, the cell internal space V1) and flows through the cell internal space V1. Once the vacuum pump 531 disposed in the separation pipe 53 operates in this state, the pressure in the separation space V2 is reduced to provide a pressure difference between the cell internal space V1 and the separation space V2. The separation membrane 51 that separates the cell internal space V1 from the separation space V2 is a membrane that allows water to pass through and does not allow IPA to pass through. Thus, when the pressure difference is provided between the cell internal space V1 and the separation space V2, water (water molecules) contained in the mixed fluid flowing into the cell internal space V1 passes through the separation membrane 51, reaches the separation space V2, and flows into the separation pipe 53 through the second outlet 523. In this manner, water is separated from the mixed fluid. In contrast, since IPA (IPA molecules) contained in the mixed fluid flowing into the cell internal space V1 cannot pass through the separation membrane 51, the IPA flows through the cell internal space V1, and flows into the dewatering circulation pipe 62 through the first outlet 522. As such, the mixed fluid containing the IPA with a concentration higher than that when entering the dewaterer 621 flows out of the dewaterer 621. Each time the mixed fluid repeatedly passes through the dewaterer 621, the concentration of the IPA in the mixed fluid increases.

### (c) Structure of Separation Pipe 53 Side

Next, a structure of the separation pipe 53 into which water (hereinafter also referred to as “separated water”) that has passed through the separation membrane 51 flows will be described below with reference to FIG. 3.

A condenser 532 that condenses the separated water is disposed upstream of the vacuum pump 531 in the separation pipe 53. A waste pipe 54 leading (guiding) the separated water condensed by the condenser 532 is connected to the condenser 532. As described above, the heater 623 heats the mixed fluid circulating through the dewatering circulation pipe 62. Thus, at least a part of the mixed fluid circulating through the dewatering circulation pipe 62 (i.e., the mixed fluid flowing into the dewaterer 621) is in the vapor state, and at least a part of the separated water that has passed through the separation membrane 51 and flows into the separation pipe 53 is also in the vapor state. The condenser 532 condenses the separated water that flows into the separation pipe 53 in the vapor state, and causes the separated water to flow into the waste pipe 54. For example, the condenser 532 may include a device (i.e., a heat exchanger) including a cooling pipe which is disposed around a pipe and through which a cooling medium (e.g., a coolant) is distributed to remove heat of a fluid flowing through the pipe and cool the fluid. Obviously, not only the separated water that flows into the separation pipe 53 in the vapor state and condensed by the condenser 532, but also the separated water that is already in the liquid state when flowing into the separation pipe 53 also flows into the waste pipe 54.

The waste pipe 54 is equipped with a decomposer 541 that decomposes the organic solvent (IPA herein) contained in the separated water flowing through the waste pipe 54. Although the separation membrane 51 is a membrane that allows water to pass through and does not allow IPA to pass through (the separation membrane 51 blocks the passage of IPA), it is inevitable that IPA passes through the separation membrane 51 in trace amounts in reality. Thus, even when the separation membrane 51 is in a normal state, it is possible that the separated water that flows into the separation pipe 53 may contain IPA in trace amounts. Here, the decomposer 541 decomposes the IPA contained in the separated water in trace amounts. Decomposing the IPA can sufficiently reduce the content of the IPA in the separated water. Furthermore, when the IPA contained in the separated water is decomposed into, for example, water and carbon dioxide, the content of water (the purity of water) in the separated water can be increased. For example, the decomposer 541 may be a device that electrolyzes IPA contained in the separated water. In this case, the decomposer 541 can include, for example, a tank that temporarily stores the separated water flowing through the waste pipe 54, a pair of electrodes to be soaked in the separated water stored in the tank, and a power supply part that supplies power to the pair of electrodes to produce a potential difference between the electrodes.

The waste pipe 54 is connected to, for example, the rinse liquid supply source 433b of the processing unit 4 (FIG. 2). Here, after the decomposer 541 decomposes the IPA contained in the separated water flowing into the waste pipe 54, the separated water is led (guided) to the rinse liquid supply source 433b through the waste pipe 54 and discharged from the rinse liquid nozzle 43b as a rinse liquid. In other words, the separated water is recycled as a rinse liquid herein. Obviously, the waste pipe 54 need not always be connected to the rinse liquid supply source 433b, and may be connected to, for example, a water collection line in a factory. Here, after the decomposer 541 decomposes the IPA contained in the separated water flowing into the waste pipe 54, the separated water is led (guided) to the water collection line in the factor through the waste pipe 54, and collected by the water collection line in the factory.

The separation pipe 53 is equipped with a concentration sensor (a concentration monitoring sensor 533) that measures the concentration of the organic solvent (IPA herein) contained in the separated water flowing through the separation pipe 53. As described above, the separation membrane 51 is a membrane that allows water to pass through and does not allow IPA to pass through. Thus, if there is no abnormality, the amount of IPA contained in the separated water that passes through the separation membrane 51 and flows into the separation pipe 53 should be sufficiently less (i.e., the concentration of the IPA contained in the separated water is sufficiently low). However, a certain abnormality (e.g., an abnormality in the separation membrane 51) may trigger an increase in the concentration of the IPA contained in the separated water. Thus, the concentration monitoring sensor 533 measures the concentration of the IPA contained in the separated water flowing through the separation pipe 53. For example, the concentration monitoring sensor 533 is disposed in the vicinity of the upstream end of the separation pipe 53. The concentration monitoring sensor 533 is connected (e.g., electrically connected) to the controller 6, and measures the concentration of IPA contained in the separated water flowing through the separation pipe 53 according to an instruction from the controller 6 to output an obtained measurement value (a measurement concentration) Dt to the controller 6.

A valve (a shut-off valve 534) that switches between allowing the separated water to flow through the separation pipe 53 and shutting off (stopping) a flow of the separated water through the separation pipe 53 is further disposed in the separation pipe 53. In other words, the separated water can flow downstream of the shut-off valve 534 (a downstream portion relative to the shut-off valve 534 of the separation pipe 53) when the shut-off valve 534 is opened, whereas the separated water is blocked (shut off) to prevent the separated water from flowing out toward a downstream side of the shut-off valve 534 when the shut-off valve 534 is closed. For example, the shut-off valve 534 is disposed downstream of the concentration monitoring sensor 533 and upstream of the condenser 532. The shut-off valve 534 is connected (e.g., electrically connected) to the controller 6, and is opened and closed according to an instruction from the controller 6. In other words, the controller 6 controls the timing to open and close the shut-off valve 534.

A valve (a water stop valve) 542 that switches between allowing the separated water to flow through the waste pipe 54 and shutting off (stopping) a flow of the separated water through the waste pipe 54 is also disposed in the waste pipe 54. In other words, the separated water can flow downstream of the water stop valve 542 (a downstream portion relative to the water stop valve 542 of the waste pipe 54) when the water stop valve 542 is opened, whereas the separated water is blocked (shut off) to prevent the separated water from flowing out toward a downstream side of the water stop valve 542 when the water stop valve 542 is closed. For example, the water stop valve 542 is disposed downstream of the decomposer 541. The water stop valve 542 is connected (e.g., electrically connected) to the controller 6, and is opened and closed according to an instruction from the controller 6. In other words, the controller 6 controls the timing to open and close the water stop valve 542.

The controller 6 determines (monitors) whether the measurement concentration Dt obtained by the concentration monitoring sensor 533 exceeds a predetermined safe concentration Ds. When determining that the measurement concentration Dt exceeds the safe concentration Ds (is higher than the safe concentration Ds), the controller 6 closes both of the shut-off valve 534 and the water stop valve 542. Closing the shut-off valve 534 shuts off (stops) a flow of the separated water through the separation pipe 53, and closing the water stop valve 542 shuts off a flow of the separated water through the waste pipe 54. The safe concentration Ds is a value lower than a lower explosion limit (LEL) De of an organic solvent (IPA herein) (Ds<De). The safe concentration Ds is, for example, 25% of the lower explosion limit De or lower (i.e., 25% of the LEL or lower). For example, the safe concentration Ds is 25% of the lower explosion limit De (i.e., 25% of the LEL).

As such, when the measurement concentration Dt obtained by the concentration monitoring sensor 533 exceeds the safe concentration Ds, the shut-off valve 534 is closed, and flowing of the separated water through the separation pipe 53 is shut off (stopped). In other words, even when a certain abnormality triggers an increase in the concentration of the IPA contained in the separated water, the shut-off valve 534 is closed before the concentration reaches the lower explosion limit De. This can prevent the separated water containing IPA with a concentration exceeding the lower explosion limit De (hereinafter also referred to as “dangerous separated water”) from flowing out toward the downstream side of the shut-off valve 534.

Since the concentration monitoring sensor 533 will need a predetermined response time, when the blocking valve 534 is closed, the probability that the separated water containing IPA with a concentration slightly exceeding the safe concentration Ds without exceeding the lower explosion limit De (hereinafter also referred to as “abnormal separated water”) flows into the downstream side of the shut-off valve 534 is not zero. However, when the measurement concentration Dt exceeds the safe concentration Ds, the water stop valve 542 is closed, and flowing of the separated water through the waste pipe 54 is shut off (stopped). This can prevent the abnormal separated water from flowing out toward the downstream side of the water stop valve 542, even if the abnormal separated water flows into the downstream side of the shut-off valve 534. Thus, the abnormal separated water does not flow into, for example, the rinse liquid supply sources 433b or a water collection line in a factory.

### (d) Purification Tank 70

The purification tank 70 is connected to the collection tank 60 through a first feed pipe 71 and the dewatering circulation pipe 62. In other words, one end of the first feed pipe 71 is connected to the purification tank 70, and the other end of the first feed pipe 71 is connected to the dewatering circulation pipe 62. For example, the other end of the first feed pipe 71 is connected to a position upstream of the dewaterer 621 and downstream of the heater 623 in the dewatering circulation pipe 62. However, the other end of the first feed pipe 71 may be directly connected to the collection tank 60, not through the dewatering circulation pipe 62. A first feed valve 711 is disposed in the first feed pipe 71. When the collection tank 60 stores a fluid in which the concentration (purity) of IPA has been sufficiently increased (the concentration of IPA is high enough to be supplied to the substrate W) (hereinafter also referred to as a “concentrated fluid”) by separating water from the mixed fluid, once the first feed valve 711 is opened, the concentrated fluid is guided by the first feed pipe 71, and flows into and is stored by the purification tank 70.

A circulation pipe (a purifying circulation pipe) 72 is connected to the purification tank 70. Specifically, both of one end and the other end of the purifying circulation pipe 72 are connected to the purification tank 70. The purifying circulation pipe 72 forms a circulation path through which the concentrated fluid stored in the purification tank 70 circulates by flowing out of the purification tank 70 and returning to the purification tank 70 again.

A pump (a purifying feed pump) 721, and an open/close valve 722 are disposed in the purifying circulation pipe 72. For example, the open/close valve 722 is disposed downstream of the purifying feed pump 721 and upstream of the purification tank 70. The purifying feed pump 721 feeds the concentrated fluid in the purifying circulation pipe 72 at a pressure necessary for circulation. The purifying feed pump 721 feeds the concentrated fluid at the pressure necessary for circulation with the open/close valve 722 being opened, so that the concentrated fluid stored in the purification tank 70 circulates through the purifying circulation pipe 72.

A filter 723 and a temperature regulator 724 are disposed in the purifying circulation pipe 72. For example, the filter 723 is disposed downstream of the purifying feed pump 721 and upstream of the purification tank 70. The temperature regulator 724 is disposed downstream of the purifying feed pump 721 and upstream of the filter 723. The filter 723 captures a removal target substance (e.g., particles and a metal) contained in the concentrated fluid flowing through the purifying circulation pipe 72. Passage of the concentrated fluid through the filter 723 removes the removal target substance contained in the concentrated fluid from the concentrated fluid, and increases the cleanliness of the concentrated fluid. An air removal pipe 7231 may be connected to the filter 723. The temperature regulator 724 is a device with a cooling capacity and a heating capacity, and is, for example, an electronic cooler/heater that electronically cools and heats an object using a Peltier element. When a fluid at a high temperature passes through the filter 723, for example, thermal expansion may cause a decrease in the performance of the filter 723. Thus, the temperature regulator 724 herein cools the concentrated fluid circulating through the purifying circulation pipe 72 to a predetermined temperature (e. g., room temperature) as necessary. This suppresses the decrease in the performance of the filter 723.

Various sensors may be disposed in the purifying circulation pipe 72. For example, a pressure sensor 725 that detects a pressure of the concentrated fluid circulating through the purifying circulation pipe 72, a temperature sensor 726 that detects the temperature of the concentrated fluid circulating through the purifying circulation pipe 72, and a particle counter (not illustrated) that counts the number of particles contained in the concentrated fluid circulating through the purifying circulation pipe 72 may be disposed in the purifying circulation pipe 72. In the example of the drawing, the pressure sensor 725 is disposed in the vicinity downstream of the purifying feed pump 721, and the temperature sensor 726 is disposed in the vicinity downstream of the temperature regulator 724.

### (e) Supply Tank 80

The supply tank 80 is connected to the purification tank 70 through a second feed pipe 81 and the purifying circulation pipe 72. In other words, one end of the second feed pipe 81 is connected to the supply tank 80, and the other end of the second feed pipe 81 is connected to the purifying circulation pipe 72. For example, the other end of the second feed pipe 81 is connected to a position upstream of the filter 723 and downstream of the purifying feed pump 721 in the purifying circulation pipe 72. However, the other end of the second feed pipe 81 may be directly connected to the purification tank 70, not through the purifying circulation pipe 72. A second feed valve 811 is disposed in the second feed pipe 81. When the purification tank 70 stores the concentrated fluid in which the cleanliness has been sufficiently increased (the cleanliness is high enough to be supplied to the substrate W) (hereinafter also referred to as a “purified fluid”), once the second feed valve 811 is opened, the purified fluid is guided by the second feed pipe 81, and flows into and is stored by the supply tank 80.

The supply tank 80 may be connected to a new liquid supply source 821 through a new liquid pipe 82. Here, one end of the new liquid pipe 82 is connected to the supply tank 80, and the other end of the new liquid pipe 82 is connected to the new liquid supply source 821. The new liquid supply source 821 is a supply source of unused IPA that has not yet been supplied to the substrate W (IPA with sufficiently high purity, specifically for example, IPA with purity of 99 wt % or higher). A new liquid valve 822 is disposed in the new liquid pipe 82. Once the new liquid valve 822 is opened, the unused IPA is guided by the new liquid pipe 82, and flows into and is stored by the supply tank 80.

The supply tank 80 is connected to the organic solvent nozzles 43c through a third feed pipe 83. In other words, one end of the third feed pipe 83 is connected to the supply tank 80, and the other end of the third feed pipe 83 is connected to the organic solvent nozzles 43c (specifically, the organic solvent pipes 432c connected to the organic solvent nozzles 43c). Here, for example, the third feed pipe 83 is connected to the organic solvent nozzles 43c included in each of the processing units 4 belonging to the same tower. A pump (a supplying feed pump) 831 is disposed in the third feed pipe 83. Once the organic solvent valves 431c are opened, the purified fluid stored in the supply tank 80 is fed by the supplying feed pump 831 to the organic solvent nozzles 43c side, and is discharged from the organic solvent nozzles 43c.

A filter 832 and a temperature regulator 833 may be disposed in the third feed pipe 83. The filter 832 captures a removal target substance contained in the purified fluid fed through the third feed pipe 83. The temperature regulator 833 regulates the temperature of the purified fluid fed through the third feed pipe 83 (i.e., heats or cools the purified fluid to a predetermined temperature). In the example of the drawing, the temperature regulator 833 is disposed downstream of the supplying feed pump 831, and the filter 832 is disposed downstream of the temperature regulator 833. Furthermore, various sensors may be disposed in the third feed pipe 83. For example, a pressure sensor 834 that detects a pressure of the purified fluid fed through the third feed pipe 83, and a temperature sensor 835 that detects the temperature of the purified fluid fed through the third feed pipe 83 may be disposed in the third feed pipe 83. In the example of the drawing, the pressure sensor 834 is disposed in the vicinity downstream of the supplying feed pump 831, and the temperature sensor 835 is disposed in the vicinity downstream of the temperature regulator 833.

### 3-2. Explosion-Proof Area

Here, an area in which IPA is handled is defined as an explosion-proof area A1. For example, electrical devices to be used in the explosion-proof area A1 (devices that are in danger of becoming sources of ignition (flammables)) are made explosion-proof to prevent the devices from becoming sources of ignition. The explosion-proof measures may be taken by appropriate methods in accordance with a defined standard. An explosion-proof measure may be taken by, for example, housing a target device in a vessel and filling the vessel with an inert gas (e.g., nitrogen gas) to purge the original atmosphere from the vessel. Alternatively, an explosion-proof measure may be taken by, for example, applying a specification (an explosion-proof specification) with which an energized portion, etc., of a target device hardly sparks.

The mixed fluid contains a large amount of IPA. Thus, an area in which the collection tank 60 storing the mixed fluid and pipes (the collection pipe 61 and the dewatering circulation pipe 62) are disposed is defined as the explosion-proof area A1. Here, the pipes are pipes through which the mixed fluid flows. In other words, the electrical devices disposed in the dewatering circulation pipe 62 (for example, the dewatering feed pump 622, the heater 623, and sensors (e.g., the concentration sensor 625, the pressure sensor 626, the temperature sensor 627, and the flow rate sensor 628) are made explosion-proof. The valves disposed in the collection pipe 61 and the dewatering circulation pipe 62 (e.g., the collection valve 611 and the pair of open/close valves 624a and 624b) are made explosion-proof when the valves are powered by electricity. However, an explosion-proof measure is not required when the valves are powered by air. As described above, the explosion-proof measures may be taken by appropriate methods. An explosion-proof measure may be taken by, for example, providing vessels K for separately housing target devices and filling the respective vessels K with an inert gas.

The concentrated fluid also contains a large amount of IPA. Thus, an area in which the purification tank 70 storing the concentrated fluid and pipes (the first feed pipe 71 and the purifying circulation pipe 72) are disposed is also defined as the explosion-proof area A1. Here, the pipes are pipes through which the condensed fluid flows. In other words, the electrical devices disposed in the purifying circulation pipe 72 (for example, the purifying feed pump 721, the temperature regulator 724, and sensors (e.g., the pressure sensor 725 and the temperature sensor 726)) are made explosion-proof. Furthermore, the valves disposed in the first feed pipe 71 and the purifying circulation pipe 72 (e.g., the first feed valve 711 and the open/close valve 722) are made explosion-proof when the valves are powered by electricity.

As described above, the separated water contains IPA in trace amounts in a normal situation (if no abnormality occurs). However, a certain abnormality may trigger an increase in the concentration of the IPA contained in the separated water. In such a case, however, it is ensured that the separated water containing IPA with a concentration exceeding the lower explosion limit De (dangerous separated water) is prevented from flowing out toward the downstream side of the shut-off valve 534 disposed in the separation pipe 53 as described above. Thus, an area downstream of the shut-off valve 534 can be defined as a non-explosion-proof area A2.

Thus, for example, an area in which a piping portion downstream of the shut-off valve 534 (a downstream piping portion 53a) in the separation pipe 53 is disposed is defined as the non-explosion-proof area A2. In other words, the electrical devices disposed in the downstream piping portion 53a (e.g., the vacuum pump 531 and the condenser 532) are not made explosion-proof. For example, even when the condenser 532 includes a flow rate sensor that measures the flow rate of a coolant to be used in the condensation, the flow rate sensor is not made explosion-proof.

Furthermore, here, an area in which the waste pipe 54 through which the separated water condensed by the condenser 532 flows is disposed is also defined as the non-explosion-proof area A2. In other words, the electrical devices disposed in the waste pipe 54 (e.g., the decomposer 541) are not made explosion-proof. Furthermore, the valves disposed in the waste pipe 54 (e.g., the water stop valve 542) are not made explosion-proof even when the valves are powered by electricity.

In the example of the drawing, an area in which a piping portion upstream of the downstream piping portion 53a (an upstream piping portion 53b) in the separation pipe 53 is disposed is defined as the explosion-proof area A1. In other words, the electrical devices disposed in the upstream piping portion 53b (e.g., the concentration monitoring sensor 533) are made explosion-proof. Furthermore, the valves disposed in the upstream piping portion 53b (e.g., the shut-off valve 534) are made explosion-proof when the valves are powered by electricity.

However, an area in which the upstream piping portion 53b is disposed may be defined as the non-explosion-proof area A2. In other words, the electrical devices disposed in the upstream piping portion 53b (e.g., the concentration monitoring sensor 533) need not be made explosion-proof. Furthermore, the valves disposed in the upstream piping portion 53b (e.g., the shut-off valve 534) need not be made explosion-proof even when the valves are powered by electricity. The reason why the area in which the upstream piping portion 53b is disposed may be defined as the non-explosion-proof area A2 is as follows. First, when the measurement concentration Dt exceeds the safe concentration Ds lower than the lower explosion limit De, the shut-off valve 534 is closed as described above. Here, even when a certain abnormality occurs in, for example, the separation membrane 51, the probability of an abrupt increase in the concentration of the IPA contained in the separated water is very low. Thus, the probability that the dangerous separated water flows into the upstream piping portion 53b when the shut-off valve 534 is closed is very low. Second, when the shut-off valve 534 is closed, the separation space V2 is isolated from the vacuum pump 531. Thus, the flow of the separated water into the separation pipe 53 is substantially stopped. Thus, the probability that the dangerous separated water flows into the upstream piping portion 53b after the shut-off valve 534 is closed is also very low. As such, closing the shut-off valve 534 when the measurement concentration Dt exceeds the safe concentration Ds not only prevents the dangerous separated water from flowing out toward the downstream piping portion 53a but also prevents the dangerous separated water from flowing into the upstream piping portion 53b. Thus, not only the area in which the downstream piping portion 53a is disposed but also the area in which the upstream piping portion 53b is disposed (i.e., an area in which the entire separation pipe 53 is disposed) can be defined as the non-explosion-proof area A2.

### 3-3. Operations

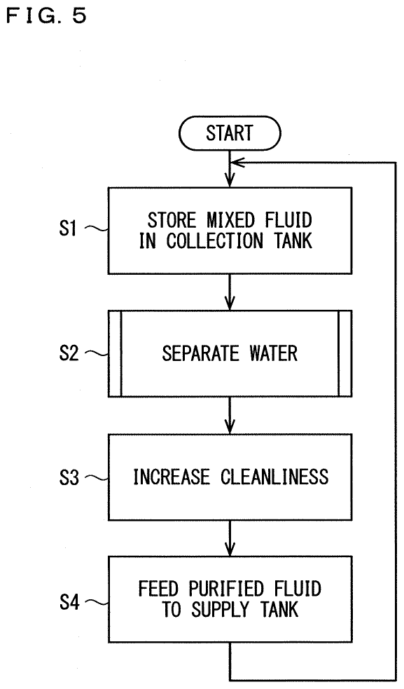

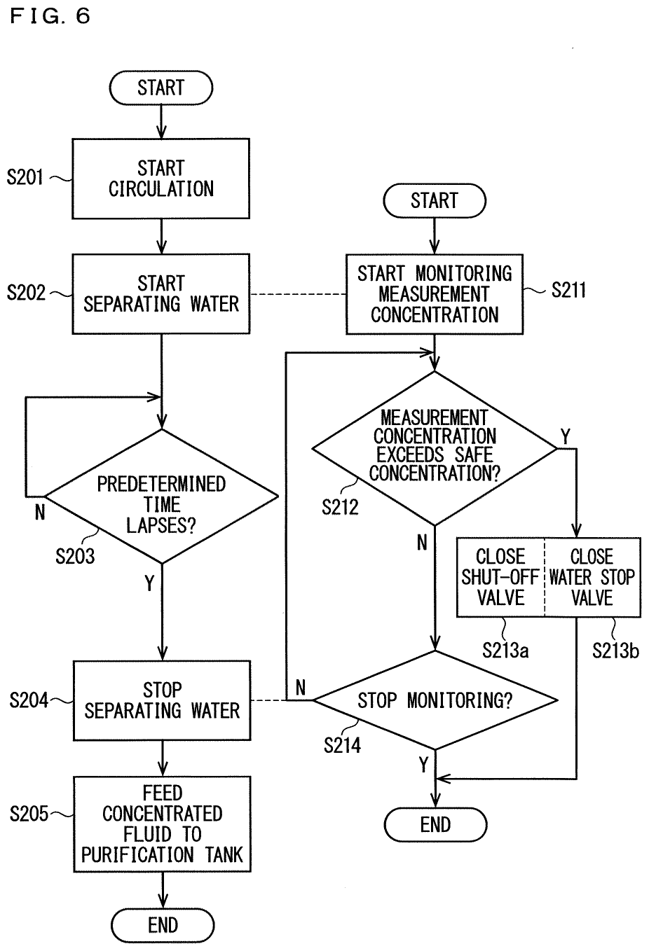

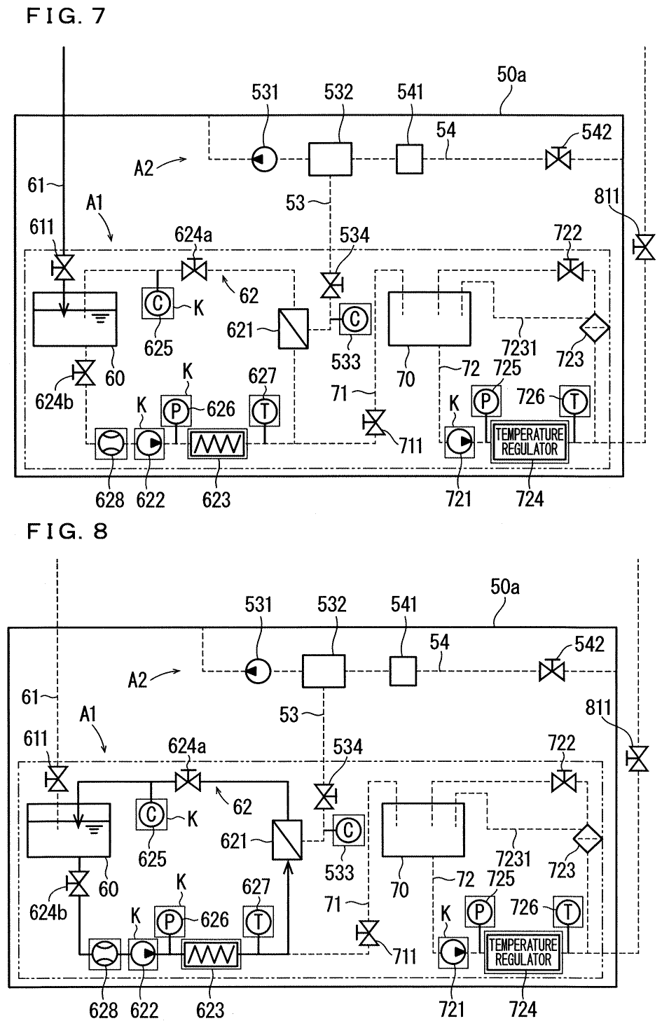

The procedure to be performed by the organic solvent collector 5 will be described with reference to FIGS. 5 to 13. FIG. 5 illustrates an example procedure to be performed by the organic solvent collector 5. FIG. 6 illustrates an example procedure for separating water from a mixed fluid and an example procedure for monitoring the concentration of IPA contained in the separated water. FIGS. 7 to 13 schematically illustrate a state of the organic solvent collector 5 in each step. In FIGS. 7 to 13, a solid line indicates a pipe through which a fluid flows, and a dashed line indicates a pipe through which a fluid does not flow for convenience in description.

The operations of the organic solvent collector 5 are performed under control of the controller 6. In other words, the controller 6 controls, for example, pumps (the dewatering feed pump 622, the vacuum pump 531, the purifying feed pump 721, and the supplying feed pump 831), valves (the shut-off valve 534, the water stop valve 542, the collection valve 611, the pair of open/close valves 624a and 624b, the first feed valve 711, the open/close valve 722, the second feed valve 811, and the new liquid valve 822, etc.), the heater 623, the condenser 532, the decomposer 541, and the temperature regulators 724 and 833, based on information input from sensors (the concentration monitoring sensor 533, the concentration sensor 625, the pressure sensors 626, 725, and 834, the temperature sensors 627, 726, and 835, and the flow rate sensor 628, etc.), so that the organic solvent collector 5 proceeds with a series of the operations.

### Step S1

First, the collection valve 611 is opened with the collection tank 60 being empty. Then, the liquid collected by the cups 42 in the organic solvent supplying step and the spin drying step is guided by the collection pipe 61, and flows into the collection tank 60. Consequently, the collection tank 60 stores the mixed fluid containing the water supplied to the substrate W and then collected and the IPA supplied to the substrate W and then collected (FIG. 7) (a storing step). When the collection tank 60 stores a predetermined quantity of the mixed fluid, the collection valve 611 is closed.

### Step S2

Then, a process of separating water from the mixed fluid stored in the collection tank 60 is performed. Furthermore, a process of monitoring the concentration of IPA contained in the separated water is performed in parallel with this process. These processes will be specifically described with reference to FIGS. 6 and 8 to 11.

### (i) Process of Separating Water from Mixed Fluid

The process of separating water from the mixed fluid stored in the collection tank 60 is performed in, for example, the following manner.

First, the pair of open/close valves 624a and 624b are opened, and the dewatering feed pump 622 feeds the mixed fluid at the circulation pressure. This allows the mixed fluid stored in the collection tank 60 to flow and circulate through the dewatering circulation pipe 62 (Step S201: a flowing step) (FIG. 8). In this stage, the heater 623 heats the mixed fluid circulating through the dewatering circulation pipe 62 to a predetermined temperature.

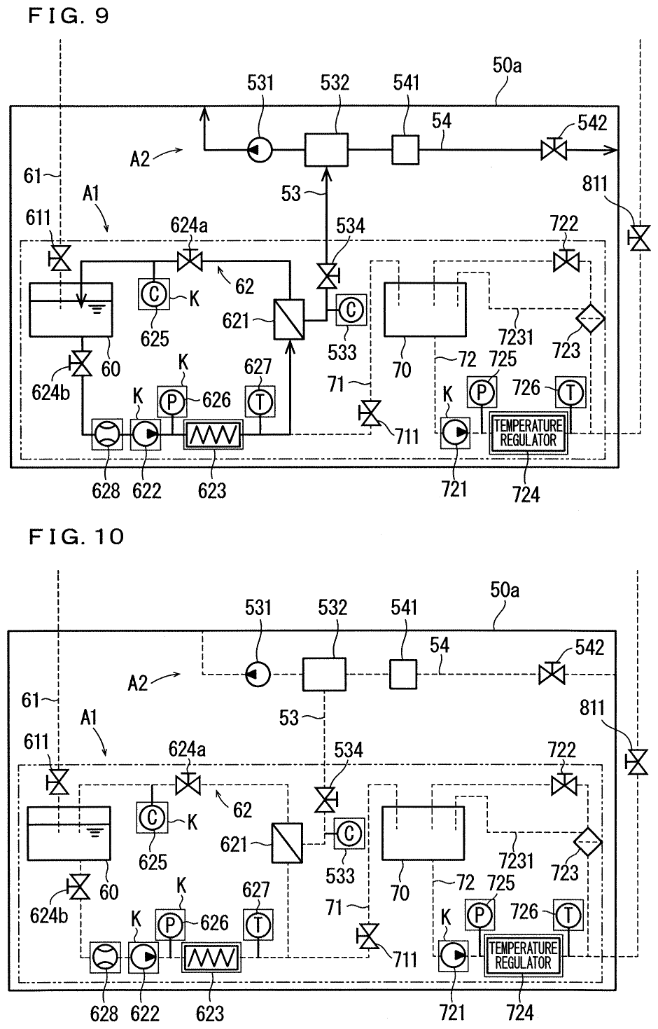

Next, the vacuum pump 531 starts to operate. Once the vacuum pump 531 operates, the pressure in the separation space V2 is reduced to provide a pressure difference between the cell internal space V1 and the separation space V2. This pressure difference allows water contained in the mixed fluid flowing into the cell internal space V1 to pass through the separation membrane 51, reach the separation space V2, and flow into the separation pipe 53. In other words, when the mixed fluid circulating through the dewatering circulation pipe 62 passes through the dewaterer 621, water contained in the mixed fluid is separated, and flows into the separation pipe 53 (Step S202: a separation step) (FIG. 9).

Then, a state where the vacuum pump 531 is operating is continued only for a predetermined time. Meanwhile, the mixed fluid circulating through the dewatering circulation pipe 62 repeatedly passes through the dewaterer 621, which increases the concentration of IPA in the mixed fluid. The time required to sufficiently increase the concentration of IPA in the mixed fluid stored in the collection tank 60 (the concentration is high enough to supply the fluid to the substrate W), that is, the time required to obtain the concentrated fluid is determined in advance through, for example, measurement and calculation, and is defined as the predetermined time. Thus, after a lapse of the predetermined time since start of operating the vacuum pump 531, the concentrated fluid is stored in the collection tank 60. After a lapse of the predetermined time since start of operating the vacuum pump 531 (YES in Step S203), the operation of the vacuum pump 531 is stopped. As a result, water separation in the dewaterer 621 is stopped (Step S204).

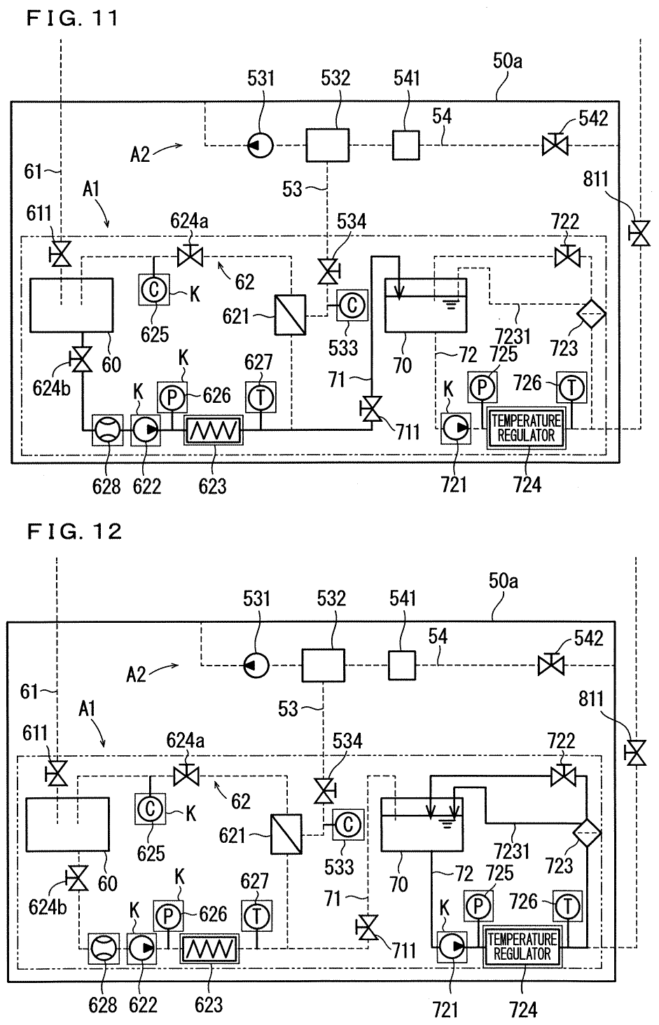

Then, the first feed valve 711 is opened. This allows the concentrated fluid stored in the collection tank 60 to be fed to the purification tank 70 through the first feed pipe 71. Thus, the concentrated fluid is stored in the purification tank 70 (Step S205) (FIG. 11). When the total quantity of the concentrated fluid stored in the collection tank 60 is fed to the purification tank 70, the first feed valve 711 is closed.

### (ii) Process of Monitoring Concentration of IPA Contained in Separated Water

The process of monitoring the concentration of IPA contained in the separated water is performed in, for example, the following manner.

Once the dewaterer 621 starts to separate water, the separated water starts to flow into the separation pipe 53. For example, once the dewaterer 621 starts to separate water (specifically, once the vacuum pump 531 starts to operate), the controller 6 starts to monitor the measurement concentration Dt (Step S211: a monitoring step). Specifically, the controller 6 causes the concentration monitoring sensor 533 to start to measure the concentration of the IPA contained in the separated water flowing through the separation pipe 53. The concentration monitoring sensor 533 outputs the obtained measurement concentration Dt to the controller 6 in real time. The controller 6 determines whether the measurement concentration Dt successively output from the concentration monitoring sensor 533 in real time exceeds the safe concentration Ds.

When determining that the measurement concentration Dt exceeds the safe concentration Ds (the measurement concentration Dt is higher than the safe concentration Ds) (Yes in Step S212), the controller 6 closes the shut-off valve 534 (Step S213a: a shutting off step) and also closes the water stop valve 542 (Step S213b: a water stopping step). Closing the shut-off valve 534 shuts off (stops) a flow of the separated water through the separation pipe 53, and closing the water stop valve 542 shuts off (stops) a flow of the separated water through the waste pipe 54 (FIG. 10). As described above, the fact that the measurement concentration Dt exceeds the safe concentration Ds indicates that a certain abnormality may occur in, for example, the separation membrane 51. Therefore, when the controller 6 determines that the measurement concentration Dt exceeds the safe concentration Ds, it is preferred to not only close the shut-off valve 534 and the water stop valve 542 but also suspend separation of water by the dewaterer 621 (specifically for example, to stop operations of the vacuum pump 531, the dewatering feed pump 622, and the heater 623, and to close the pair of open/close valves 624a and 624b).

When the dewaterer 621 stops separating water (specifically, the operation of the vacuum pump 531 is stopped) without the measurement concentration Dt successively output in real time from the concentration monitoring sensor 533 exceeding the safe concentration Ds, the controller 6 stops monitoring the measurement concentration Dt (Yes in Step S214). When water separation in the dewaterer 621 is properly stopped without suspending the separation in midstream (Step S204), after the concentrated fluid stored in the collection tank 60 is fed to the purification tank 70 (Step S205), the processes proceed to the process in Step S3.

### Step S3

Next, a process of increasing the cleanliness of the concentrated fluid stored in the purification tank 70 is performed. Specifically, the open/close valve 722 is opened, and the purifying feed pump 721 feeds the concentrated fluid at the pressure necessary for circulation. This allows the concentrated fluid stored in the purification tank 70 to circulate through the purifying circulation pipe 72 (FIG. 12). This state is continued only for a predetermined time. Meanwhile, the concentrated fluid circulating through the purifying circulation pipe 72 repeatedly passes through the filter 723, which increases the cleanliness of the concentrated fluid. Here, the time required to sufficiently increase the cleanliness of the concentrated fluid circulating through the purifying circulation pipe 72 (the cleanliness is high enough to supply the fluid to the substrate W), that is, the time required to obtain the purified fluid is determined in advance through, for example, measurement and calculation, and is defined as the predetermined time. Thus, after a lapse of the predetermined time since start of the circulation, the purified fluid is stored in the purification tank 70. After a lapse of the predetermined time since start of the circulation, the open/close valve 722 is closed.

### Step S4

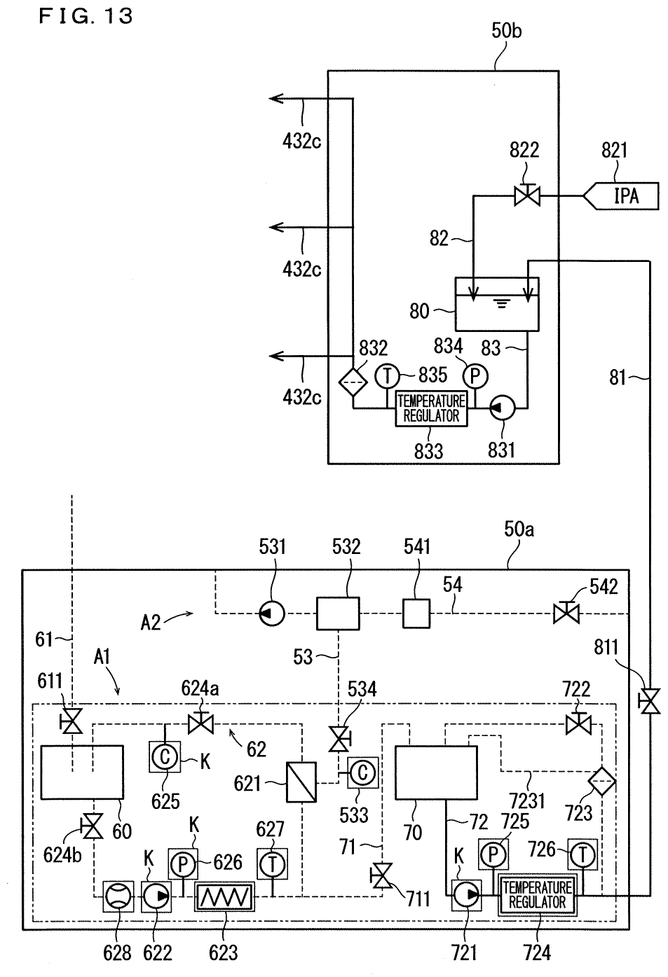

Next, the second feed valve 811 is opened. This allows the purified fluid in the purification tank 70 to be fed to the supply tank 80 through the second feed pipe 81. Thus, the purified fluid is stored in the supply tank 80 (FIG. 13). For example, when the total quantity of the purified fluid in the purification tank 70 is fed to the supply tank 80, the second feed valve 811 is closed. Then, once the organic solvent valves 431c are opened, the purified fluid stored in the supply tank 80 is fed by the supplying feed pump 831 to the organic solvent nozzles 43c side, and is discharged from the organic solvent nozzles 43c. In other words, the purified fluid is supplied to the substrates W. At some midpoint of the passage through the third feed pipe 83, the purified fluid may pass through the filter 832 to increase the cleanliness, or the temperature of the purified fluid may be regulated by the temperature regulator 833 as necessary. Furthermore, when the quantity of the purified fluid stored in the supply tank 80 is less than a predetermined quantity, the new liquid valve 822 may be opened to refill unused IPA in the supply tank 80.

In the organic solvent collector 5, the aforementioned series of processes (Steps S1 to S4) is repeated. However, a process in next Step S1 may be performed prior to the end of the process in Step S4 (e.g., at the completion of the process in Step S3).

### 4. Advantages

The substrate processing apparatus 100 according to the embodiment above includes: a rinse liquid supply nozzle (the rinse liquid nozzle 43b) that supplies the substrate W with a rinse liquid containing water; an organic solvent supply nozzle (the organic solvent nozzle 43c) that supplies an organic solvent (e.g., IPA) to the substrate W; the collection tank 60 that stores a mixed fluid containing the water supplied to the substrate W and then collected and the organic solvent supplied to the substrate W and then collected; the dewaterer 621 disposed in a pipe (the dewatering circulation pipe 62) connected to the collection tank 60, and including the separation membrane 51 that allows the water to pass through and does not allow the organic solvent to pass through; the separation pipe 53 which is connected to the dewaterer 621 and into which separated water that has passed through the separation membrane 51 flows; the concentration monitoring sensor 533 that measures a concentration of the organic solvent contained in the separated water; the shut-off valve 534 disposed in the separation pipe 53, and shutting off a flow of the separated water through the separation pipe 53 when the shut-off valve 534 is in a closed state; and the controller 6 that closes the shut-off valve 534 when the concentration (the measurement concentration Dt) of the organic solvent measured by the concentration monitoring sensor 533 exceeds the safe concentration Ds lower than the lower explosion limit De of the organic solvent.

When a certain abnormality causes the concentration of the organic solvent contained in the separated water to exceed the safe concentration Ds lower than the lower explosion limit De, the shut-off valve 534 is closed according to this structure. This can prevent the separated water (dangerous separated water) containing the organic solvent with the concentration exceeding the lower explosion limit De from flowing out toward the downstream side of the shut-off valve 534. Thus, even when the area downstream of the shut-off valve 534 is defined as the non-explosion-proof area A2 (i.e., even when the devices disposed downstream of the shut-off valve 534 are not made explosion-proof), safety is ensured. In other words, the explosion-proof area A1 can be narrowed without compromising safety. Narrowing the explosion-proof area A1 can reduce the number of the devices requiring the explosion-proof measures. This can, for example, reduce the cost, and can make the apparatus more compact.

The substrate processing apparatus 100 according to the embodiment above further includes the condenser 532 disposed at a position downstream of the shut-off valve 534 in the separation pipe 53 and condensing the separated water, and the waste pipe 54 leading the separated water condensed by the condenser 532. This structure can condense the separated water that flows into the separation pipe 53 and lead the condensed separated water to the waste pipe 54. Furthermore, since the condenser 532 is disposed downstream of the shut-off valve 534, the condenser 532 and the devices disposed in the waste pipe 54 do not require explosion-proof measures.

The substrate processing apparatus 100 according to the embodiment above further includes the water stop valve 542 disposed in the waste pipe 54 and shutting off a flow of the separated water through the waste pipe 54 when the water stop valve 542 is in a closed state. The controller 6 closes the water stop valve 542 when the measurement concentration Dt exceeds the safe concentration Ds. Even if the separated water (abnormal separated water) containing an organic solvent with a concentration slightly exceeding the safe concentration Ds without exceeding the lower explosion limit De flows into the downstream side of the shut-off valve 534, this structure can prevent such separated water from flowing out toward the downstream side of the water stop valve 542. In other words, this structure can prevent the abnormal separated water from flowing into, for example, the rinse liquid supply source 433b or a water collection line in a factory.

The substrate processing apparatus 100 according to the embodiment above further includes the decomposer 541 that decomposes the organic solvent contained in the separated water flowing through the waste pipe 54. Even when the separated water flowing into the waste pipe 54 contains the organic solvent in trace amounts, the organic solvent can be decomposed. Thus, the content of the organic solvent in the separated water can be sufficiently reduced. Furthermore, since the decomposer 541 is disposed downstream of the shut-off valve 534, the decomposer 541 does not require the explosion-proof measures.

In the embodiment above, the separated water is led to, for example, the rinse liquid supply nozzle (the rinse liquid nozzle 43b) through the waste pipe 54, and is supplied to the substrate W as a rinse liquid. Under this structure, the water separated from the mixed fluid containing the water supplied to the substrate W and then collected and the organic solvent supplied to the substrate W and then collected is again supplied to the substrate W as a rinse liquid. Thus, the amount of water to be used can be reduced.

The substrate processing apparatus 100 according to the embodiment above further includes: the purification tank 70 connected to the collection tank 60 through a feed pipe (the first feed pipe 71) and storing the concentrated fluid obtained by separating water from the mixed fluid; and the filter 723 disposed in a pipe (the purifying circulation pipe 72) connected to the purification tank 70 and capturing a removal target substance contained in the concentrated fluid flowing through the purifying circulation pipe 72. This structure can increase the cleanliness of the concentrated fluid obtained by separating water from the mixed fluid, by removing the removal target substance from the concentrated fluid.

In the embodiment above, the concentrated fluid stored in the purification tank 70 is fed to the organic solvent nozzles 43c through the filter 723, and is supplied to the substrates W. In other words, after the cleanliness of the concentrated fluid obtained by separating water from the mixed fluid containing the water supplied to the substrate W and then collected and the organic solvent supplied to the substrate W and then collected is increased, the concentrated fluid is again supplied to the substrates W. Thus, the amounts of the organic solvent to be used and to be discharged can be reduced (saving liquid). IPA is a volatile organic compound (VOC), so reduction of the amounts of IPA to be used and to be discharged can mitigate the environmental load.

### 5. Modifications

The structure and operations of the substrate processing apparatus 100 according to the embodiment above can be appropriately modified. In the following description, the same reference numerals are assigned to the same elements described in the embodiment above, and the description thereof will be omitted.

### 5-1. First Modification

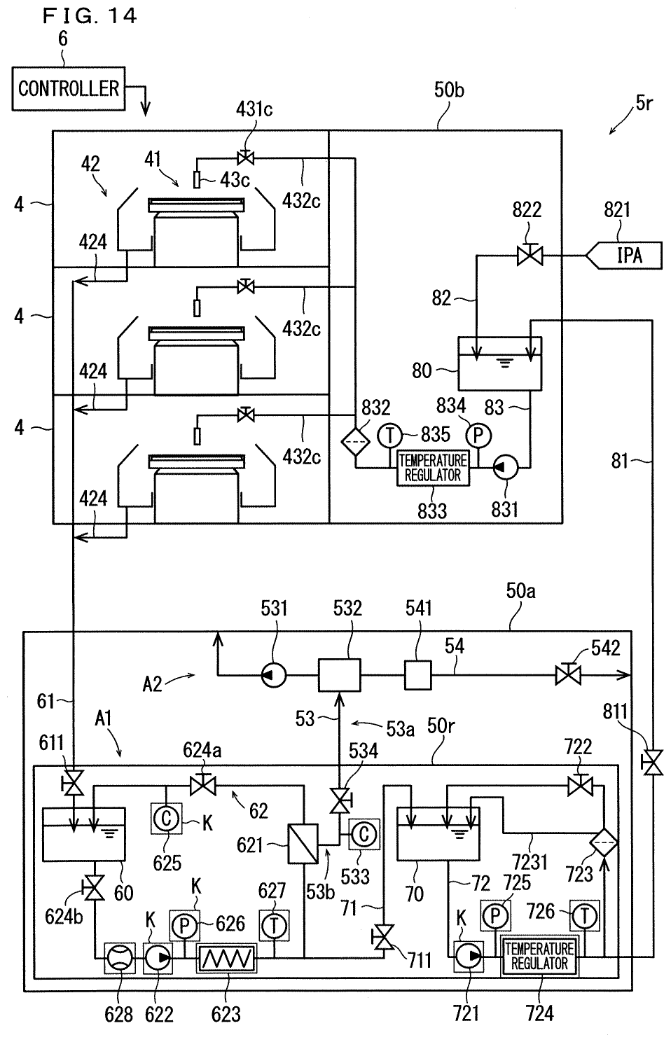

An organic solvent collector 5r according to the first modification will be described with reference to FIG. 14. FIG. 14 schematically illustrates an example of the organic solvent collector 5r.

The organic solvent collector 5r includes an enclosure 50r housing a part or the entirety of the devices disposed in the explosion-proof area A1. The enclosure 50r seals the inner portion airtight. The enclosure 50r houses, specifically for example, the collection tank 60, the dewatering circulation pipe 62, and the devices disposed in this dewatering circulation pipe 62 (the dewaterer 621, the dewatering feed pump 622, the heater 623, the pair of open/close valves 624a and 624b, and the sensors 625, 626, 627, and 628). The enclosure 50r further houses the purification tank 70, the first feed pipe 71, the purifying circulation pipe 72, and the devices disposed in these pipes (the first feed valve 711, the purifying feed pump 721, the open/close valve 722, the filter 723, the temperature regulator 724, and the sensors 725 and 726). The collection pipe 61, the separation pipe 53, and the second feed pipe 81 are disposed to penetrate the enclosure 50r. In the case of the collection pipe 61, for example, a downstream piping portion of the collection pipe 61 is disposed in the enclosure 50r, and the collection pipe 61 penetrates the enclosure 50r in midstream, and an upstream piping portion of the collection pipe 61 is disposed outside the enclosure 50r. In the case of the separation pipe 53, for example, the upstream piping portion 53b of the separation pipe 53 is disposed in the enclosure 50r, and the separation pipe 53 penetrates the enclosure 50r in midstream, and the downstream piping portion 53a of the separation pipe 53 is disposed outside the enclosure 50r. In the case of the second feed pipe 81, an upstream piping portion of the second feed pipe 81 is disposed in the enclosure 50r, and the second feed pipe 81 penetrates the enclosure 50r in midstream, and an downstream piping portion of the second feed pipe 81 is disposed outside the enclosure 50r. A portion of the enclosure 50r in which the collection pipe 61, the separation pipe 53, or the second feed pipe 81 penetrates is preferably sealed airtight by, for example, a sealant.

Even when an organic solvent (e.g., IPA) leaks inside the enclosure 50r due to an unforeseen situation, the IPA can be confined inside the enclosure 50r according to this modification. Even when such an unforeseen situation arises, it is possible to avoid a leak of IPA into the non-explosion-proof area A2 and enhance safety. The enclosure 50r may be filled with an inert gas (e.g., nitrogen gas). The enclosure 50r may be an explosion-proof vessel (a vessel of strength that can withstand the explosion).

### 5-2. Second Modification

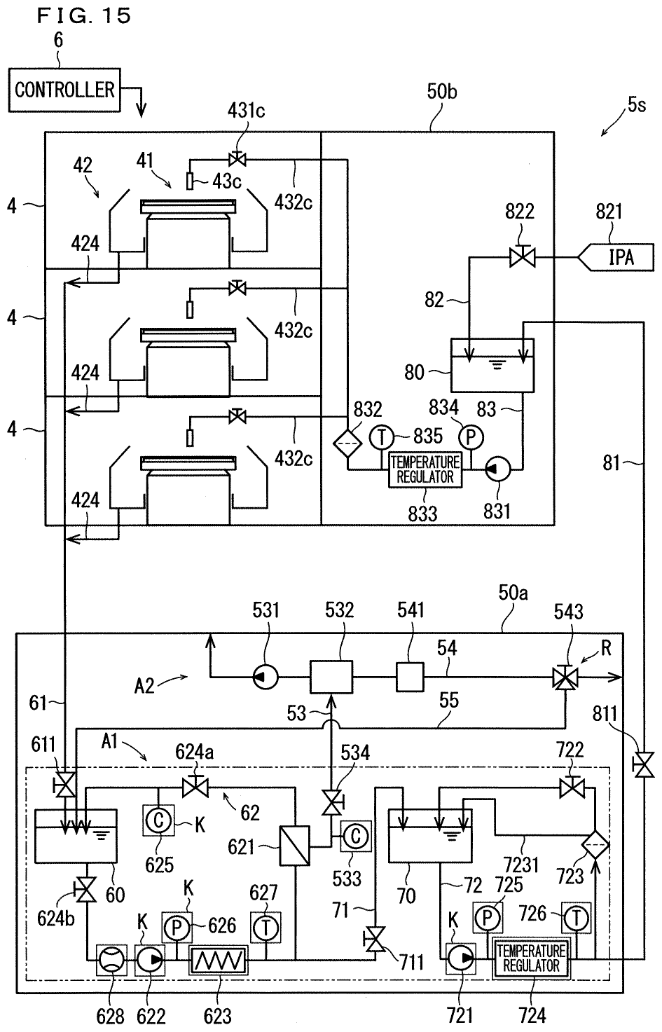

An organic solvent collector 5s according to the second modification will be described with reference to FIG. 15. FIG. 15 schematically illustrates an example of the organic solvent collector 5s.

The concentration monitoring sensor 533 and the shut-off valve 534 are disposed in the separation pipe 53 in the organic solvent collector 5s, similarly to the organic solvent collector 5 according to the embodiment above. The waste pipe 54 is equipped with a return pipe 55 and a channel switching valve 543 in the organic solvent collector 5s.

The return pipe 55 connects a branch position R defined in midstream of the waste pipe 54 to the collection tank 60. In other words, one end of the return pipe 55 is connected to the branch position R defined in midstream of the waste pipe 54, and the other end thereof is connected to the collection tank 60. For example, the branch position R is defined downstream of the decomposer 541.

The channel switching valve 543 is disposed in the branch position R, and is switchable between a first state and a second state. The first state is a state in which the separated water flowing from an upstream side of the waste pipe 54 (an upstream portion relative to the branch position R of the waste pipe 54) flows into a downstream side of the waste pipe 54 (a downstream portion relative to the branch position R of the waste pipe 54) without flowing into the return pipe 55. The second state is a state in which the separated water flowing from the upstream side of the waste pipe 54 (an upstream portion relative to the branch position R of the waste pipe 54) flows into the return pipe 55. The channel switching valve 543 may be, specifically for example, a three-way valve (a cross valve) or may include a plurality of valves. The channel switching valve 543 is connected (e.g., electrically connected) to the controller 6, and switches between the first state and the second state according to an instruction from the controller 6. In other words, the controller 6 controls the states of the channel switching valve 543.

The controller 6 determines (monitors) whether the measurement concentration Dt obtained by the concentration monitoring sensor 533 exceeds the safe concentration Ds. When determining that the measurement concentration Dt exceeds the safe concentration Ds, the controller 6 closes the shut-off valve 534, and switches the channel switching valve 543 from the first state to the second state. Closing the shut-off valve 534 shuts off a flow of the separated water through the separation pipe 53. Furthermore, switching the channel switching valve 543 from the first state to the second state allows the separated water in the waste pipe 54 to return to the collection tank 60 through the return pipe 55.

As such, when the measurement concentration Dt obtained by the concentration monitoring sensor 533 exceeds the safe concentration Ds, the shut-off valve 534 is closed. This can prevent the dangerous separated water from flowing out toward the downstream side of the shut-off valve 534. Also, when the measurement concentration Dt exceeds the safe concentration Ds, the controller 6 switches the channel switching valve 543 from the first state to the second state. Even if the abnormal separated water flows into the downstream side of the shut-off valve 534, the abnormal separated water can return to the collection tank 60 without flowing out toward the downstream side of the channel switching valve 543. Thus, the abnormal separated water does not flow into, for example, the rinse liquid supply source 433b or a water collection line in a factory, and can return to the collection tank 60 and be recycled.

### 5-3. Other Modifications

Although the process of monitoring the concentration of IPA contained in the separated water is performed while the dewaterer 621 separates water (specifically, while the vacuum pump 531 is operating) in the embodiment above, the process may be continuously performed while the dewaterer 621 does not separate water. For example, irrespective of whether the vacuum pump 531 is operating, the process may be always performed while the mixed fluid circulates through the dewatering circulation pipe 62. Furthermore, the process may be always performed, for example, while the substrate processing apparatus 100 is operating.

In the embodiment above, the water stop valve 542 may be omitted. For example, when the response time of the concentration monitoring sensor 533 is sufficiently short or when the safe concentration Ds is a sufficiently lower value, in the case where it is determined that the measurement concentration Dt exceeds the safe concentration Ds, immediately closing the shut-off valve 534 will probably sufficiently prevent the separated water containing IPA with a concentration exceeding an allowable range (an allowable range of concentration of IPA that is allowed to flow into, for example, the rinse liquid supply source 433b or a water collection line) from flowing out toward the downstream side of the shut-off valve 534. In such a case, the water stop valve 542 can be omitted.

The organic solvent collector 5 according to the embodiment above may include an enclosure housing a part or the entirety of the devices disposed in the non-explosion-proof area A2. The enclosure preferably seals the inner portion in a liquid-tight manner. The enclosure houses, specifically for example, the downstream piping portion 53a of the separation pipe 53, the devices disposed in the downstream piping portion 53a (the vacuum pump 531 and the condenser 532), the waste pipe 54, and the devices disposed in the waste pipe 54 (the decomposer 541 and the water stop valve 542). The separation pipe 53 is disposed to penetrate the enclosure. In other words, the downstream piping portion 53a of the separation pipe 53 is disposed in the enclosure, and the separation pipe 53 penetrates the enclosure in midstream, and the upstream piping portion 53b of the separation pipe 53 is disposed outside the enclosure. A portion of the enclosure in which the separation pipe 53 penetrates is preferably sealed in a liquid-tight manner by, for example, a sealant. Even when liquids of various types (e.g., a separated liquid and a coolant) leak inside the enclosure due to unforeseen situations, the liquids can be confined inside the enclosure according to this modification.

A plurality of the collection tanks 60 may be disposed in the embodiment above. When the plurality of the collection tanks 60 are disposed, even during the process of separating water from the mixed fluid stored in one of the collection tanks 60, the liquid collected by the cups 42 can be fed to the other of the collection tanks 60. In other words, switching between the collection tanks 60 that are feeding destinations can feed the liquid collected by the cups 42 (i.e., the water supplied to the substrate W and then collected and the organic solvent supplied to the substrate W and then collected) without interruption. This can shorten the cycle time from collecting the organic solvent supplied to the substrate W until supplying the organic solvent again to the substrate W. Consequently, the amounts of the organic solvent to be used and to be discharged can be effectively reduced.

A plurality of the purification tanks 70 may be disposed in the embodiment above. When the plurality of the purification tanks 70 are disposed, even during the process of increasing the cleanliness of the concentrated fluid by one of the purification tanks 70, the concentrated fluid obtained by the collection tank 60 can be fed to the other of the purification tanks 70. This can shorten the cycle time from collecting the organic solvent supplied to the substrate W until supplying the organic solvent again to the substrate W. Consequently, the amounts of the organic solvent to be used and to be discharged can be effectively reduced.

In the organic solvent collector 5 according to the embodiment above, one tank may be shared as the collection tank 60 and the purification tank 70. Specifically, for example, the dewatering circulation pipe 62 and the purifying circulation pipe 72 may be connected to one tank (a collection purification tank). Here, a mixed fluid stored in the collection purification tank may be first circulated through the dewatering circulation pipe 62 to obtain a concentrated fluid. Then, the obtained concentrated fluid may be circulated through the purifying circulation pipe 72 to obtain a purified fluid.

In the organic solvent collector 5 according to the embodiment above, a filter may be disposed in the dewatering circulation pipe 62. In other words, a removal target substance may be removed from the mixed fluid circulating through the dewatering circulation pipe 62 while water is separated from the mixed fluid. Here, the purification tank 70 may be omitted, and the collection tank 60 may be directly connected to the supply tank 80 (not through the purification tank 70).

In the organic solvent collector 5 according to the embodiment above, the structure of the dewaterer 621 can be appropriately modified. For example, the separation membrane 51 included in the dewaterer 621 is not limited to a zeolite membrane. The separation membrane 51 may be, for example, an organic separation membrane. The organic separation membrane is, for example, an organic membrane made of polyvinyl alcohol, chitosan, or polyimide. Alternatively, the separation membrane 51 may be a carbon nanotube (CNT) separation membrane. The CNT separation membrane is, for example, a membrane obtained by adding carbon nanotube to a membrane made of, for example, polyamide. Alternatively, the separation membrane 51 may be made of a two-dimensional material. The two-dimensional material is a material consisting of an atomic monolayer, specifically, for example, molybdenum sulfide (MoS₂), and a composite atomic layer compound containing an early transition metal (titanium, vanadium, etc.) and a light element (carbon or nitrogen). Alternatively, the separation membrane 51 may be made of a metal-organic framework (MOF) material, or a carbon material (e.g., graphene, graphene oxide, etc.).

In the substrate processing apparatus 100 according to the embodiment above, the processing units 4 from and to which the organic solvent collector 5 collects and supplies an organic solvent need not be the processing units 4 included in the same tower. In other words, the organic solvent collector 5 may collect and supply an organic solvent from and to at least one of the processing units 4 arbitrarily chosen. Furthermore, the processing unit 4 from which the organic solvent collector 5 collects an organic solvent may be different from the processing unit 4 to which the organic solvent collector 5 supplies an organic solvent.

In the substrate processing apparatus 100 according to the embodiment above, an organic solvent is not limited to IPA. The organic solvent may be, for example, at least one of hydrofluoroethers (HFE), methanol, ethanol, acetone, or trans-1,2-dichloroethylene. The organic solvent need not consist of a single component, but may be a liquid obtained by mixing a plurality of components.

In the substrate processing apparatus 100 according to the embodiment above, a rinse liquid may be of a variety of types which contain water. The rinse liquid may be, for example, one of carbonated water, electrolytic ionized water, hydrogen water, ozonized water, or a diluted hydrochloric acid (for example, a hydrochloric acid having a dilution concentration of 10 to 100 ppm)

The substrate W to be processed by the substrate processing apparatus 100 according to the embodiment above need not always be a semiconductor substrate. Examples of the substrate W to be processed may include a photolithographic mask glass substrate, a liquid crystal display glass substrate, a plasma display glass substrate, a field-emission display (FED) substrate, an optical disk substrate, a magnetic disk substrate, and a magneto-optical disk substrate. The substrate W to be processed need not be completely circular but may have a shaped portion such as a notch and an orientation flat.

Although the substrate processing apparatus and the substrate processing method are described above in detail, the description is in all aspects illustrative and does not restrict the substrate processing apparatus and the substrate processing method. Therefore, numerous modifications and variations that have not yet been exemplified are devised without departing from the scope of the present disclosure. The structures described in the embodiment and the modifications can be appropriately combined or omitted unless any contradiction occurs.

The present disclosure includes the following aspects.

The first aspect is a substrate processing apparatus, and includes: a rinse liquid supply nozzle that supplies a substrate with a rinse liquid containing water; an organic solvent supply nozzle that supplies an organic solvent to the substrate; a collection tank that stores a mixed fluid containing the water supplied to the substrate and then collected and the organic solvent supplied to the substrate and then collected; a dewaterer disposed in a pipe connected to the collection tank, and including a separation membrane that allows the water to pass through and does not allow the organic solvent to pass through; a separation pipe which is connected to the dewaterer and into which separated water that has passed through the separation membrane flows,; a concentration monitoring sensor that measures a concentration of the organic solvent contained in the separated water; a shut-off valve disposed in the separation pipe, and shutting off (stopping) a flow of the separated water through the separation pipe when the shut-off valve is in a closed state; and a controller that closes the shut-off valve when the concentration of the organic solvent measured by the concentration monitoring sensor exceeds a safe concentration lower than a lower explosion limit of the organic solvent.

The second aspect is the substrate processing apparatus according to the first aspect, and includes a condenser disposed at a position downstream of the shut-off valve in the separation pipe, the condenser condensing the separated water; and a waste pipe leading the separated water condensed by the condenser.

The third aspect is the substrate processing apparatus according to the second aspect, and includes a water stop valve disposed in the waste pipe, and shutting off (stopping) a flow of the separated water through the waste pipe when the water stop valve is in the closed state, wherein the controller closes the water stop valve when the concentration of the organic solvent measured by the concentration monitoring sensor exceeds the safe concentration.

The fourth aspect is the substrate processing apparatus according to the second aspect, and includes a return pipe that connects a branch position defined in midstream of the waste pipe to the collection tank; and a channel switching valve disposed in the branch position, the channel switching valve being switchable between a first state and a second state, the first state being a state in which the separated water flowing from an upstream portion relative to the branch position (an upstream side) of the waste pipe flows into a downstream portion relative to the branch position (a downstream side) of the waste pipe without flowing into the return pipe, the second state being a state in which the separated water flowing from the upstream portion relative to the branch position (an upstream side) of the waste pipe flows into the return pipe, wherein the controller switches the channel switching valve from the first state to the second state when the concentration of the organic solvent measured by the concentration monitoring sensor exceeds the safe concentration.

The fifth aspect is the substrate processing apparatus according to any one of the second to fourth aspects, and includes a decomposer that decomposes the organic solvent contained in the separated water flowing through the waste pipe.

The sixth aspect is the substrate processing apparatus according to any one of the second to fifth aspects, wherein the separated water is led to the rinse liquid supply nozzle through the waste pipe, and is supplied to the substrate as the rinse liquid.

The seventh aspect is the substrate processing apparatus according to any one of the first to sixth aspects, and includes an enclosure that houses the collection tank, the pipe, and the dewaterer, wherein the separation pipe is disposed to penetrate the enclosure.

The eighth aspect is a substrate processing method and includes: supplying a substrate with a rinse liquid containing water; supplying an organic solvent to the substrate; storing, in a collection tank, a mixed fluid containing the water supplied to the substrate and then collected and the organic solvent supplied to the substrate and then collected; causing the mixed fluid stored in the collection tank to flow through a pipe in which a dewaterer is disposed, the dewaterer including a separation membrane that allows the water to pass through and does not allow the organic solvent to pass through; causing separated water to flow into a separation pipe, the separated water being separated from the mixed fluid flowing into the dewaterer; determining whether a concentration of the organic solvent contained in the separated water flowing through the separation pipe exceeds a safe concentration lower than a lower explosion limit of the organic solvent; and closing a shut-off valve disposed in the separation pipe when it is determined that the concentration of the organic solvent exceeds the safe concentration to shut off a flow of the separated water through the separation pipe.

When a certain abnormality causes the concentration of the organic solvent contained in the separated water to exceed the safe concentration lower than the lower explosion limit, the shut-off valve is closed according to each of the first to eighth aspects. This can prevent the separated water containing the organic solvent with the concentration exceeding the lower explosion limit from flowing out toward the downstream side of the shut-off valve. Thus, even when the area downstream of the shut-off valve is defined as the non-explosion-proof area (i.e., even when the devices disposed downstream of the shut-off valve are not made explosion-proof), safety is ensured. In other words, the explosion-proof area can be narrowed without compromising safety.

According to the second aspect, the separated water that flows into the separation pipe can be condensed and led to the waste pipe. Furthermore, since the condenser is disposed downstream of the shut-off valve, the condenser and the devices disposed in the waste pipe do not require explosion-proof measures.

Even if the separated water containing an organic solvent with a concentration

slightly exceeding the safe concentration without exceeding the lower explosion limit flows into the downstream side of the shut-off valve, the third aspect can prevent such separated water from flowing out toward the downstream side of the water stop valve.

Even if the separated water containing the organic solvent with the concentration slightly exceeding the safe concentration without exceeding the lower explosion limit flows into the downstream side of the shut-off valve, such separated water can return to the collection tank without flowing out toward the downstream side of the channel switching valve according to the fourth aspect.

Even when the separated water flowing into the waste pipe contains the organic solvent in trace amounts, the organic solvent can be decomposed according to the fifth aspect. Thus, the content of the organic solvent in the separated water can be sufficiently reduced. Furthermore, since the decomposer is disposed downstream of the shut-off valve, the decomposer does not require the explosion-proof measures.

According to the sixth aspect, the water separated from the mixed fluid containing the water supplied to the substrate and then collected and the organic solvent supplied to the substrate and then collected is again supplied to the substrate as a rinse liquid. Thus, the amount of water to be used can be reduced.

Even when an organic solvent leaks inside an enclosure due to an unforeseen situation, the organic solvent can be confined inside the enclosure according to the seventh aspect.

While the disclosure has been shown and described in detail, the foregoing description is in all aspects illustrative and not restrictive. It is therefore understood that numerous modifications and variations can be devised.

What is claimed is:

1. A substrate processing apparatus, comprising:
a rinse liquid supply nozzle that supplies a substrate with a rinse liquid containing water;
an organic solvent supply nozzle that supplies an organic solvent to the substrate;
a collection tank that stores a mixed fluid containing the water supplied to the substrate and then collected and the organic solvent supplied to the substrate and then collected;
a dewaterer disposed in a pipe connected to the collection tank, and including a separation membrane that allows the water to pass through and does not allow the organic solvent to pass through;
a separation pipe which is connected to the dewaterer and into which separated water that has passed through the separation membrane flows;
a concentration monitoring sensor that measures a concentration of the organic solvent contained in the separated water;
a shut-off valve disposed in the separation pipe, and shutting off a flow of the separated water through the separation pipe when the shut-off valve is in a closed state; and
a controller that closes the shut-off valve when the concentration of the organic solvent measured by the concentration monitoring sensor exceeds a safe concentration lower than a lower explosion limit of the organic solvent.

2. The substrate processing apparatus according to claim 1, further comprising:
a condenser disposed at a position downstream of the shut-off valve in the separation pipe, the condenser condensing the separated water; and
a waste pipe leading the separated water condensed by the condenser.

3. The substrate processing apparatus according to claim 2, further comprising
a water stop valve disposed in the waste pipe, and shutting off a flow of the separated water through the waste pipe when the water stop valve is in the closed state,
wherein the controller closes the water stop valve when the concentration of the organic solvent measured by the concentration monitoring sensor exceeds the safe concentration.

4. The substrate processing apparatus according to claim 2, further comprising:
a return pipe that connects a branch position defined in midstream of the waste pipe to the collection tank; and
a channel switching valve disposed in the branch position, the channel switching valve being switchable between a first state and a second state, the first state being a state in which the separated water flowing from an upstream portion relative to the branch position of the waste pipe flows into a downstream portion relative to the branch position of the waste pipe without flowing into the return pipe, the second state being a state in which the separated water flowing from the upstream portion relative to the branch position of the waste pipe flows into the return pipe,
wherein the controller switches the channel switching valve from the first state to the second state when the concentration of the organic solvent measured by the concentration monitoring sensor exceeds the safe concentration.

5. The substrate processing apparatus according to claim 2, further comprising
a decomposer that decomposes the organic solvent contained in the separated water flowing through the waste pipe.

6. The substrate processing apparatus according to claim 2,
wherein the separated water is led to the rinse liquid supply nozzle through the waste pipe, and is supplied to the substrate as the rinse liquid.

7. The substrate processing apparatus according to claim 1, further comprising
an enclosure that houses the collection tank, the pipe, and the dewaterer,
wherein the separation pipe is disposed to penetrate the enclosure.

8. A substrate processing method, comprising:
supplying a substrate with a rinse liquid containing water;
supplying an organic solvent to the substrate;
storing, in a collection tank, a mixed fluid containing the water supplied to the substrate and then collected and the organic solvent supplied to the substrate and then collected;
causing the mixed fluid stored in the collection tank to flow through a pipe in which a dewaterer is disposed, the dewaterer including a separation membrane that allows the water to pass through and does not allow the organic solvent to pass through;
causing separated water to flow into a separation pipe, the separated water being separated from the mixed fluid flowing into the dewaterer;
determining whether a concentration of the organic solvent contained in the separated water flowing through the separation pipe exceeds a safe concentration lower than a lower explosion limit of the organic solvent; and
closing a shut-off valve disposed in the separation pipe when it is determined that the concentration of the organic solvent exceeds the safe concentration to shut off a flow of the separated water through the separation pipe.
